(19) United States
(12) Patent Application Publication
(10) Pub. No.: US 2017/0221777 A1
(43) Pub. Date: Aug. 3, 2017

(54) METHOD OF MANUFACTURING SEMICONDUCTOR DEVICE AND METHOD OF FORMING MASK

(71) Applicant: MIE FUJITSU SEMICONDUCTOR LIMITED, Kuwana-shi (JP)

(72) Inventor: Toshio Sawano, Kuwana (JP)

(73) Assignee: MIE FUJITSU SEMICONDUCTOR LIMITED, Kuwana-shi (JP)

(21) Appl. No.: 15/386,950

(22) Filed: Dec. 21, 2016

(30) Foreign Application Priority Data
Jan. 28, 2016 (JP) 2016-014877

(51) Int. Cl. H01L 21/66; H01L 21/768; H01L 21/033

(52) U.S. Cl. CPC H01L 22/12; H01L 21/0332; H01L 21/7681

(57) ABSTRACT

A first mask with a first pattern is formed above a substrate, a first portion is formed in or above the substrate using the first mask, a second mask with a second pattern is formed above the substrate, a first positional deviation between the first portion and the second pattern is measured, a second portion is formed in or above the substrate using the second mask, a third mask with a third pattern is formed above the substrate, and a third portion is formed in or above the substrate using the third mask. In the forming the third mask, the third pattern is formed in a material film for the third mask with alignment in consideration of the first positional deviation.

### CROSS-REFERENCE TO RELATED APPLICATION

This application is based upon and claims the benefit of priority of the prior Japanese Patent Application No. 2016-014877, filed on Jan. 28, 2016, the entire contents of which are incorporated herein by reference.

### FIELD

The embodiments discussed herein are directed to a method of manufacturing a semiconductor device and a method of forming a mask.

### BACKGROUND

A mask formed with a pattern is used for processing such as etching and ion implantation in manufacture of a semiconductor device. Therefore, it is important to perform accurate alignment with a portion which has been formed before in or above a semiconductor substrate for manufacturing a semiconductor device with high accuracy. For performing alignment with two portions, a pattern is formed based on one of the portions, a positional deviation from the one and a positional deviation from the other one of the portions are measured, and then whether these positional deviations fall within an allowable range is judged.

However, the portion which has been formed before cannot be clearly detected and the positional deviation between the portion and the pattern formed in the mask cannot be measured in some cases. For example, an impurity implanted region formed by ion implantation such as a well cannot be optically detected. Therefore, after formation of a pattern for forming a gate electrode, the positional deviation from the well cannot be measured. Further, in the case of performing alignment with an opening portion for wiring trench formed in a hard mask by a dual damascene method of trench first approach, as the hard mask is thinner, the opening portion is lower in optical contrast and is thus difficult to clearly optically detect in some cases. In this case, even if the positional deviation from the opening portion for wiring trench is measured after the formation of the pattern for forming via hole, its result has low reliability.

[Patent Document 1] Japanese Laid-open Patent Publication No. 03-262111

### SUMMARY

According to an aspect of the embodiments, a method of manufacturing a semiconductor device, includes: forming a first mask with a first pattern above a substrate; forming a first portion in or above the substrate using the first mask; forming a second mask with a second pattern above the substrate; measuring a first positional deviation between the first portion and the second pattern; forming a second portion in or above the substrate using the second mask; forming a third mask with a third pattern above the substrate, the forming the third mask comprising forming the third pattern in a material film for the third mask with alignment in consideration of the first positional deviation; and forming a third portion in or above the substrate using the third mask.

According to another aspect of the embodiments, a method of forming a mask, includes: forming a material film for mask above a substrate with a first portion and a second portion therein or thereabove; and forming a pattern in the material film, wherein the forming the pattern comprises performing alignment in consideration of a deviation between the first portion and a pattern in a mask used in forming the second portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a flowchart illustrating a method of manufacturing a semiconductor device according to a first embodiment;

FIG. 2 is a flowchart illustrating a method of alignment when a third mask is formed in the first embodiment;

FIGS. 3A to 3E are charts illustrating a positional deviation and an adjustment parameter to the positional deviation in the first embodiment;

FIGS. 4A to 4C are charts illustrating another example of a positional deviation and an adjustment parameter to the positional deviation;

FIG. 5 is a flowchart illustrating a method of alignment when a third mask is formed in a reference example;

FIG. 6A to FIG. 6D are charts illustrating a positional deviation and an adjustment parameter to the positional deviation in the reference example;

FIG. 7A to FIG. 7D are charts illustrating changes in positional deviation;

FIG. 8A to FIG. 8H are cross-sectional views illustrating a method of manufacturing a semiconductor device according to a second embodiment in the order of steps;

FIG. 9A to FIG. 9G are cross-sectional views illustrating a method of manufacturing a semiconductor device according to a third embodiment in the order of steps;

FIG. 9H is a view illustrating positional relationship among inspection mark arrangement regions;

FIG. 10A to FIG. 10N are cross-sectional views illustrating a method of manufacturing a semiconductor device according to a fourth embodiment in the order of steps;

FIG. 11A and FIG. 11B are views illustrating adjustment of shift deviation in one shot;

FIG. 12A and FIG. 12B are views illustrating adjustment of magnification deviation in one shot;

FIG. 13A and FIG. 13B are views illustrating adjustment of rotational deviation in one shot;

FIG. 14A and FIG. 14B are views illustrating adjustment of shift deviation in one wafer;

FIG. 15A and FIG. 15B are views illustrating adjustment of magnification deviation in one wafer; and

FIG. 16A and FIG. 16B are views illustrating adjustment of rotational deviation in one wafer.

### DESCRIPTION OF EMBODIMENT

Hereinafter, embodiments will be concretely described referring to the accompanying drawings.

### First Embodiment

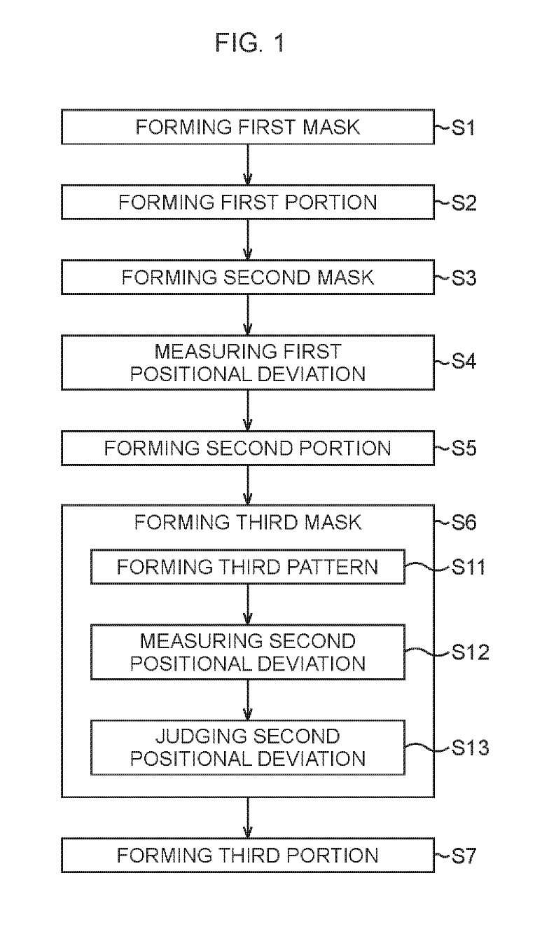

First, a first embodiment will be described. FIG. 1 is a flowchart illustrating a method of manufacturing a semiconductor device according to the first embodiment.

In the first embodiment, as illustrated in FIG. 1, a first mask with a first pattern is formed above a substrate (Step S1), a first portion is formed in or above the substrate using the first mask (Step S2), and a second mask with a second pattern is formed above the substrate (Step S3). A first positional deviation between the first portion and the second pattern is measured (Step S4), a second portion is formed in or above the substrate using the second mask (Step S5), and a third mask with a third pattern is formed above the substrate (Step S6). A third portion is formed in or above the substrate using the third mask (Step S7). In Step S6, the third pattern is formed in a material film for the third mask with alignment in consideration of the first positional deviation (Step S11), a second positional deviation between the first portion and the third pattern is measured (Step S12), and the second positional deviation is judged (Step S13). Etching, ion implantation, and forming a film by lift-off method are exemplified as the forming the first portion, the forming the second portion, and the forming the third portion.

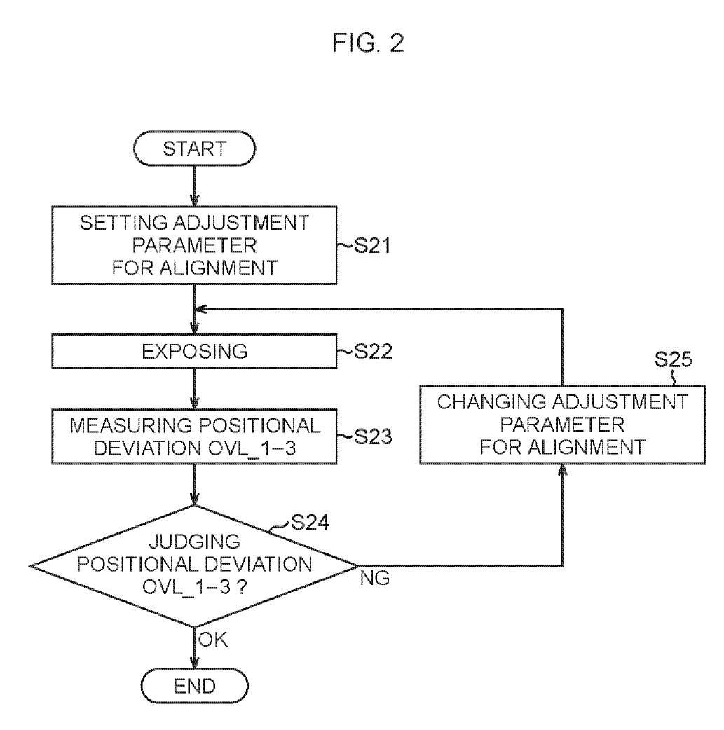

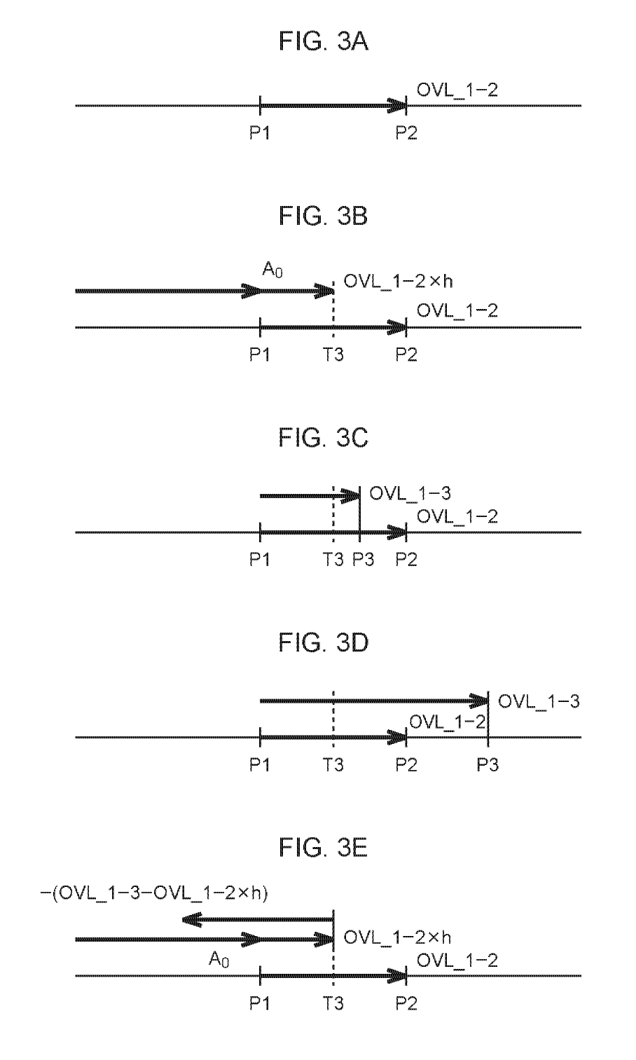

Here, an effect of reducing positional deviation when a photoresist film is used as the material film for the third mask and the third pattern is formed in the photoresist film by photolithography technology will be described. FIG. 2 is a flowchart illustrating a method of alignment when the third mask is formed in the first embodiment. FIGS. 3A to 3E are charts illustrating a positional deviation and an adjustment parameter to the positional deviation in the first embodiment. In the following description, a positional deviation has a direction and a magnitude in which the magnitude of the positional deviation in a specific direction has a positive value and the magnitude of the positional deviation in the direction opposite thereto has a negative value.

As illustrated in FIG. 3A, the first portion is formed at a position P1 corresponding to the first pattern by the processes in Steps S1 to S2, and the second portion is formed at a position P2 corresponding to the second pattern by the processes in Steps S3 to S5. The positional deviation of the position P2 from the position P1 is expressed as “OVL_1-2”. This positional deviation OVL_1-2 is measured in Step S4.

In this embodiment, the third pattern is formed in the material film for the third mask, namely, the photoresist film with alignment in consideration of the positional deviation OVL_1-2 is (Step S11).

In this event, prior to transfer of a pattern of a photomask to the photoresist film using an exposure apparatus, a parameter obtained by adding a parameter reflecting the positional deviation OVL_1-2 to an adjustment parameter A₀ for aligning the third pattern with the position P1 is set as an adjustment parameter A in the exposure apparatus (Step S21). For example, as illustrated in FIG. 3B, a parameter obtained by adding a product of the positional deviation OVL_1-2 and a correction coefficient h (0≦h≦1) to the adjustment parameter A₀ is used as the adjustment parameter A. The correction coefficient h is a value based on a level in which the positional deviation between the third portion and the first and the second portions is allowed. A value closer to 1 is used as the correction coefficient h in a case where the positional deviation between the third portion and the first portion is allowed at a higher level than the positional deviation between the third portion and the second portion, and 0.5 is used as the correction coefficient h in a case where the positional deviations are allowed at the same level. In this manner, a target position T3 of the third pattern is decided.

After the setting of the adjustment parameter A (Step S21), exposure using the exposure apparatus is performed to transfer the pattern of the photomask to the photoresist film, and the photoresist film is developed (Step S22). In the exposure, alignment using the adjustment parameter A is performed. This alignment is performed, for example, by a function provided in the exposure apparatus.

Then, a positional deviation OVL_1-3 of a position P3 of the third pattern from the position P1 is measured (Step S23). There may be not only a case where the third pattern is formed near the target position T3 as illustrated in FIG. 3C, but also a case where the third pattern is formed far away from the target position T3 as illustrated in FIG. 3D. Step S23 corresponds to Step S12.

Thereafter, the positional deviation OVL_1-3 is judged (Step S24). In this event, since there is a deviation corresponding to a product of the positional deviation OVL_1-2 and the correction coefficient h (OVL_1-2×h) between the target position T3 and the position P1 as illustrated in FIG. 3B, judgement is performed in consideration of the deviation. For example, the product (OVL_1-2×h) is subtracted from the positional deviation OVL_1-3, and whether the magnitude of the obtained difference falls within an allowable range based on 0 is judged.

If the positional deviation OVL_1-3 falls within the allowable range, the third portion is formed using the thus formed third mask (Step S7). On the other hand, if the positional deviation OVL_1-3 does not fall within the allowable range, the adjustment parameter A is changed (Step S25). In the change of the adjustment parameter A, a parameter obtained by subtracting the positional deviation OVL_1-3 from the adjustment parameter A before change is used as an adjustment parameter A after change. Then, processes in Step S22 and thereafter are performed using the adjustment parameter A after change.

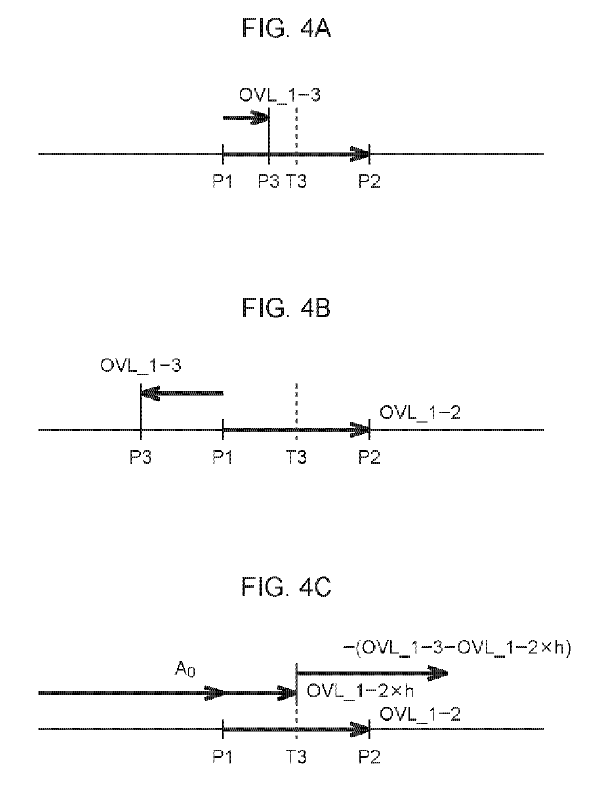

Though the position P3 is located on the positive side of the target position T3 in FIG. 3C and FIG. 3D, there is a case where the position P3 is located on the negative side of the target position T3 as illustrated in FIG. 4A and FIG. 4B. Also in this case, if the positional deviation OVL_1-3 does not fall within the allowable range, a parameter obtained by subtracting the positional deviation OVL_1-3 from the adjustment parameter A before change is used as the adjustment parameter A after change as illustrated in FIG. 4C. Then, processes in Step S22 and thereafter are performed using the adjustment parameter A after change.

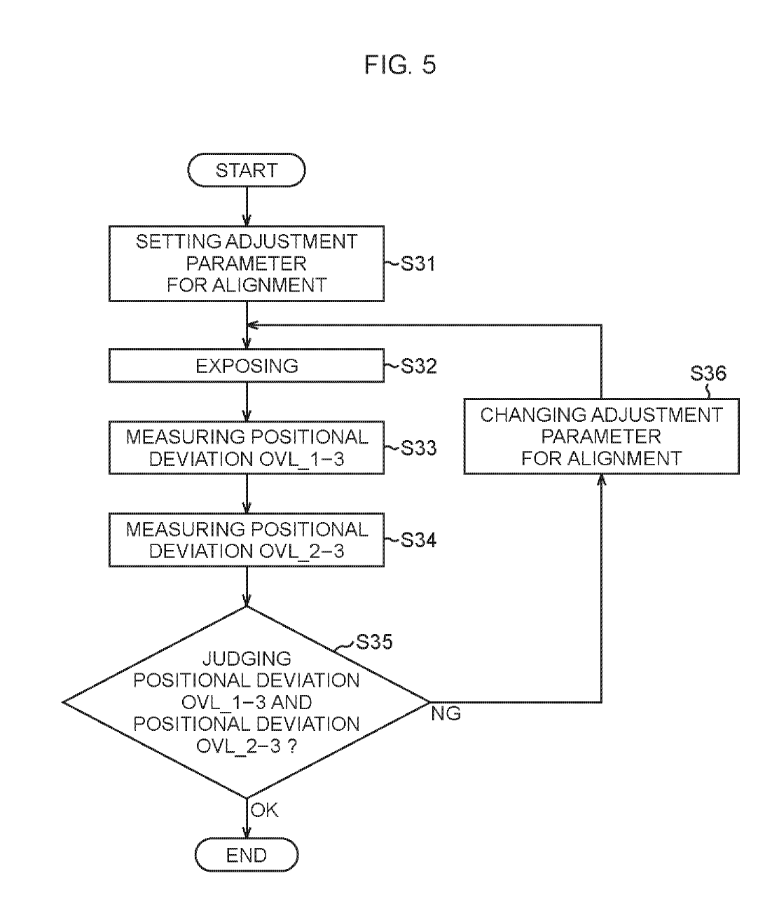

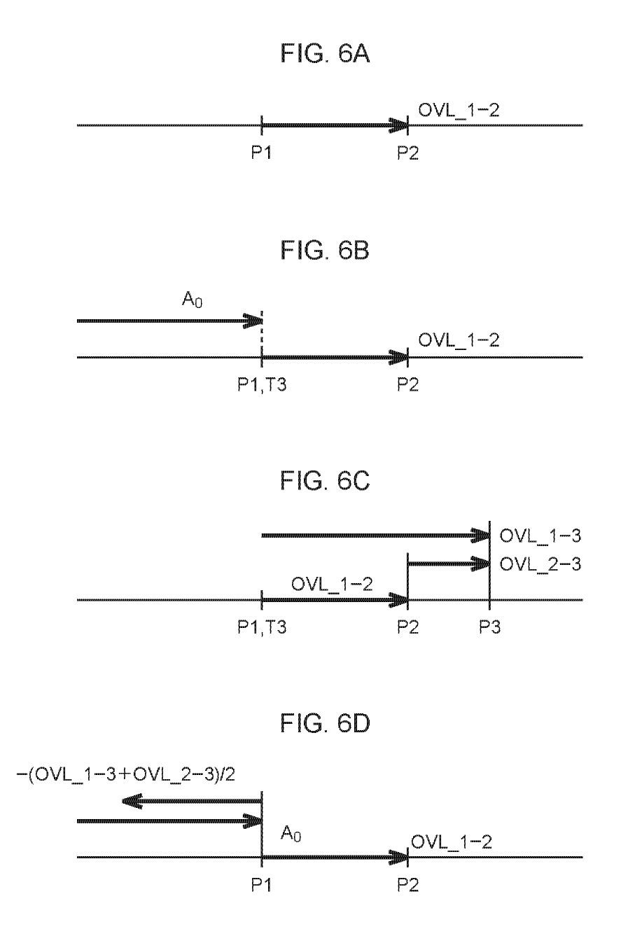

Here, for comparison, a reference example in which initial alignment of the third pattern is performed based only on the positional relationship with the position P1 will be described. FIG. 5 is a flowchart illustrating a method of alignment when the third mask is formed in the reference example. FIG. 6A to FIG. 6D are charts illustrating a positional deviation and an adjustment parameter to the positional deviation in the reference example.

As illustrated in FIG. 6A, the first portion is formed at the position P1 corresponding to the first pattern by the processes in Steps S1 to S2, and the second portion is formed at the position P2 corresponding to the second pattern by the processes in Steps S3 to S5. The positional deviation OVL_1-2 is measured in Step S4.

In this reference example, the third pattern is formed in the material film for the third mask, namely, the photoresist film with alignment in which the positional deviation OVL_1-2 is not taken into consideration.

In this case, prior to transfer of the pattern of the photomask to the photoresist film using the exposure apparatus, the adjustment parameter A₀ for aligning the third pattern with the position P1 is set as the adjustment parameter A in the exposure apparatus as illustrated in FIG. 6B (Step S31). In this manner, the target position T3 of the third pattern is decided.

After the setting of the adjustment parameter A (Step S31), exposure using the exposure apparatus is performed to transfer the pattern of the photomask to the photoresist film, and the photoresist film is developed (Step S32). In the exposure, alignment with the first portion using the adjustment parameter A is performed. This alignment is performed, for example, by a function provided in the exposure apparatus.

Then, as illustrated in FIG. 6C, the positional deviation OVL_1-3 of the position P3 of the third pattern from the position P1 is measured (Step S33), and a positional deviation OVL_2-3 of the position P3 from the position P2 is measured (Step S34).

Thereafter, the positional deviation OVL_1-3 and the positional deviation OVL_2-3 are judged (Step S35).

Then, if both the positional deviation OVL_1-3 and the positional deviation OVL_2-3 fall within an allowable range, the third portion is formed using the thus formed third mask. On the other hand, if at least one of the positional deviation OVL_1-3 and the positional deviation OVL_2-3 does not fall within the allowable range, the adjustment parameter A is changed (Step S36). In the change of the adjustment parameter A, a parameter obtained by subtracting an average of the positional deviation OVL_1-3 and the positional deviation OVL_2-3 from the adjustment parameter A before change is used as an adjustment parameter A after change as illustrated in FIG. 6D. Then, processes in Step S32 and thereafter are performed using the adjustment parameter A after change.

According to the first embodiment, even if the second portion is a portion which is difficult to optically detect, such as an impurity implanted region or a region with low contrast, the positional relationship with the second portion can be reflected in the alignment of the third pattern. Besides, the measurement of the positional deviation OVL_2-3 is necessary for determination of the alignment accuracy (Step S35) in the reference example, whereas this process is not necessary in the first embodiment. Therefore, according to the first embodiment, the number of steps can be made less than that in the reference example. Further, even when a positional deviation margin between the third portion and the first portion and a positional deviation margin between the third portion and the second portion are different, alignment in which the degree of difference is reflected can be performed only by adjusting the correction coefficient h.

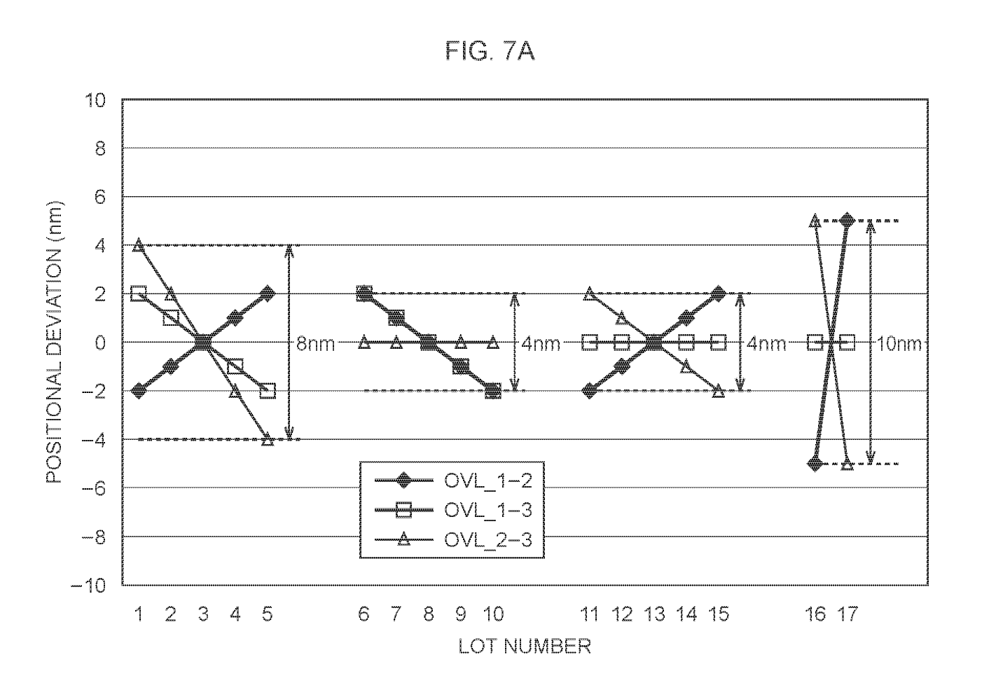

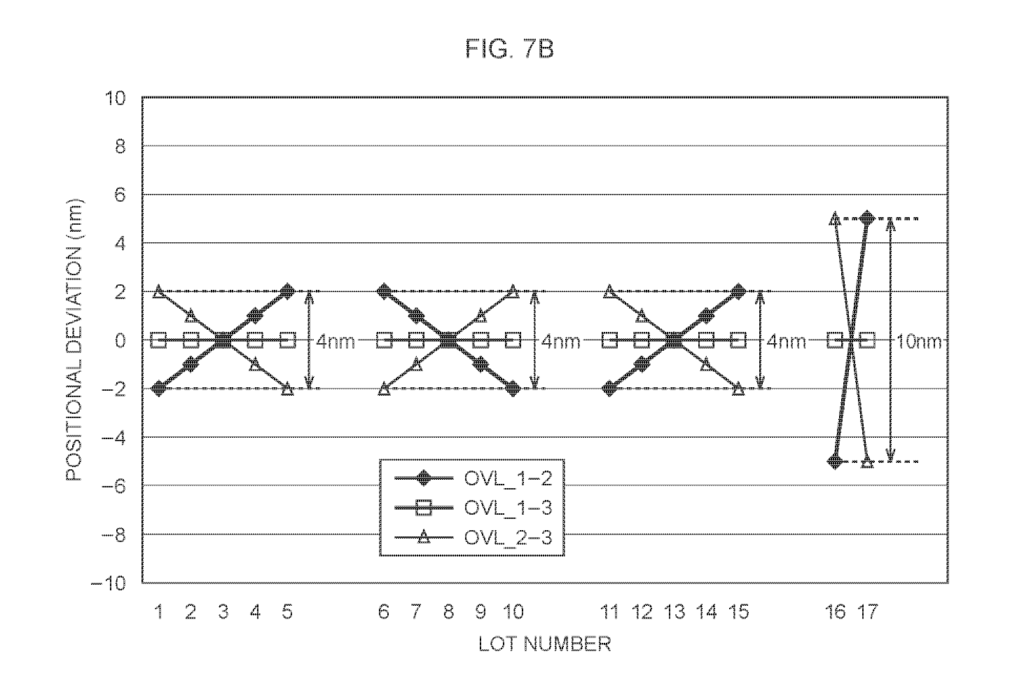

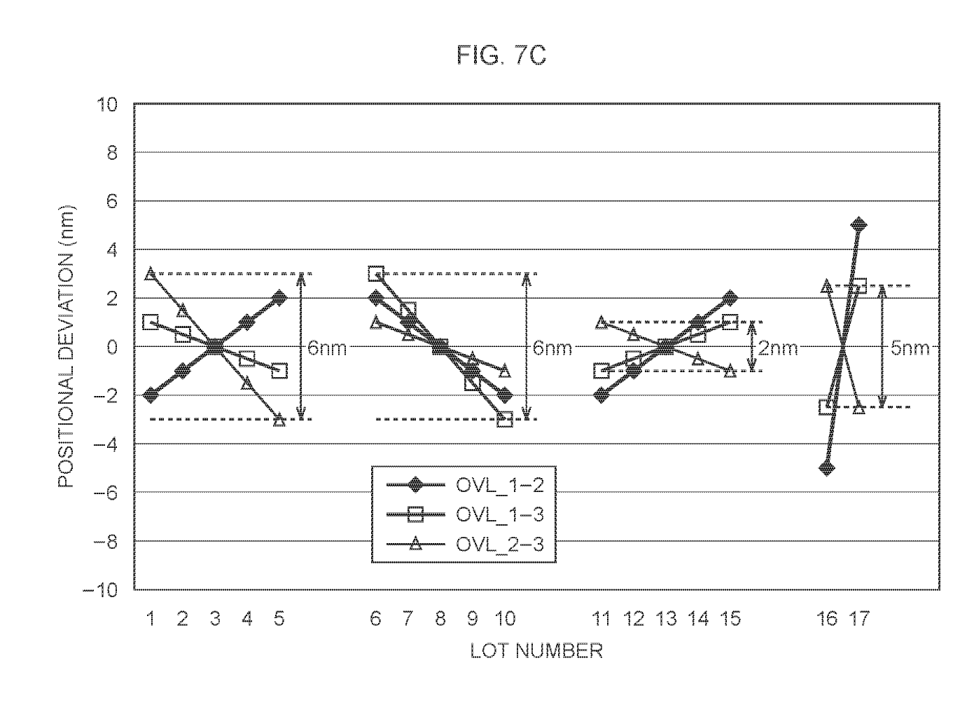

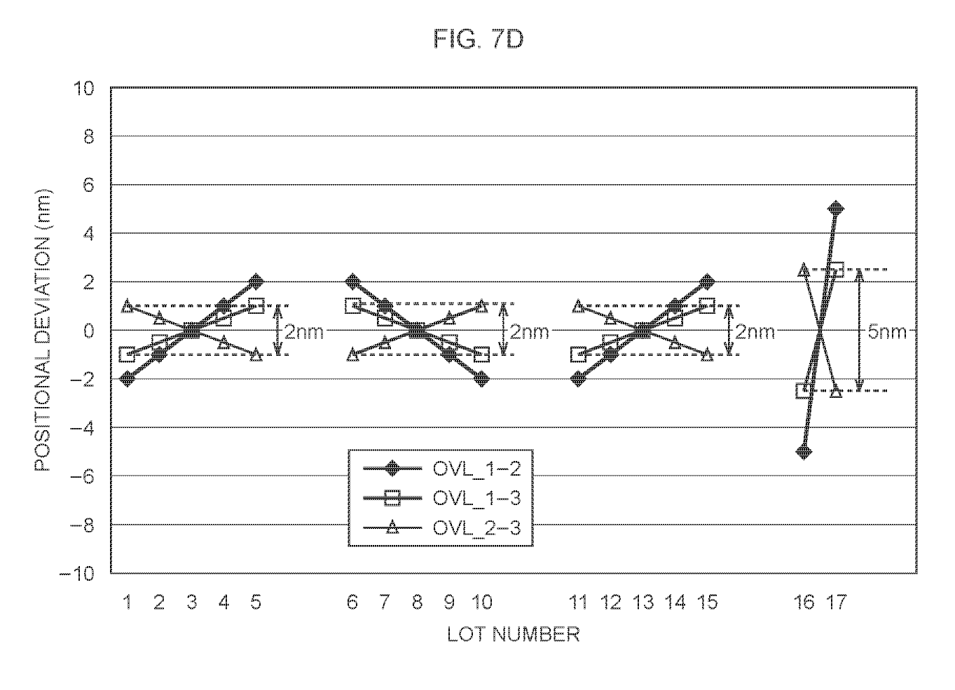

Next, the alignment accuracy according to the first embodiment will be further described. FIG. 7A to FIG. 7D are charts illustrating changes in positional deviation. Here, changes in positional deviation in 17 lots will be described, 25 wafers being processed in one lot.

As illustrated in FIG. 7A, it is assumed that the positional deviation OVL_1-2 of the second portion from the first portion and the positional deviation OVL_1-3 of the third portion from the first portion positional are the same in magnitude and directed in opposite directions from each other in lot numbers 1 to 5. It is assumed that the positional deviation OVL_1-2 and the positional deviation OVL_1-3 are the same in magnitude and directed in the same direction with each other in lot numbers 6 to 10. It is assumed that the positional deviation OVL_1-2 in lot numbers 11 to 15 is the same as that in the lot numbers 1 to 5 and the positional deviation OVL_1-3 is 0. It is assumed that the positional deviation OVL_1-2 in lot numbers 16 to 17 is 2.5 times that in the lot numbers 1 to 5 and the positional deviation OVL_1-3 is 0. In these lots, if the adjustment parameter A₀ is used as the adjustment parameter A for the alignment of the third pattern as in the reference example illustrated in FIG. 5, the positional deviation OVL_2-3 of the third portion from the second portion corresponds to a result of adding the positional deviation OVL_1-2 after it is reversed to the positional deviation OVL_1-3 as illustrated in FIG. 7A.

And, if it is judged that the change of the adjustment parameter A is necessary in Step S35 but the second portion cannot be optically detected, the adjustment parameter A is changed so that the positional deviation OVL_1-3 will be 0 as illustrated in FIG. 7B. As a result, the distribution ranges of the positional deviation OVL_1-3 and the positional deviation OVL_2-3 are narrowed in the lot numbers 1 to 5, but there are no changes recognized in the distribution ranges of the positional deviation OVL_1-3 and the positional deviation OVL_2-3 in the lot numbers 6 to 17. As described above, the method in the reference example cannot appropriately change the parameter A if the second portion cannot be optically detected.

On the other hand, in the first embodiment, when the positional deviation OVL_1-2 is the same as that in FIG. 7A, the positional deviation OVL_1-3 is different from that in FIG. 7A and the positional deviation OVL_2-3 is also different from that in FIG. 7A. More specifically, as illustrated in FIG. 7C, the positional deviation OVL_1-3 changes by an amount corresponding to the product of the positional deviation OVL_1-2 and the correction coefficient h included in the adjustment parameter A, and the positional deviation OVL_2-3 also changes according thereto. Here, the correction coefficient h is 0.5.

And, if it is judged that the change of the adjustment parameter A is necessary in Step S24, the adjustment parameter A is changed so that the positional deviation between the target position and the position of the third pattern will be 0. As a result, as illustrated in FIG. 7D, the distribution ranges of the positional deviation OVL_1-3 and the positional deviation OVL_2-3 are narrowed in all of the lot numbers 1 to 17. As described above, according to the first embodiment, even if the second portion cannot be optically detected, the parameter A can be appropriately changed, and satisfactory alignment can be performed.

### Second Embodiment

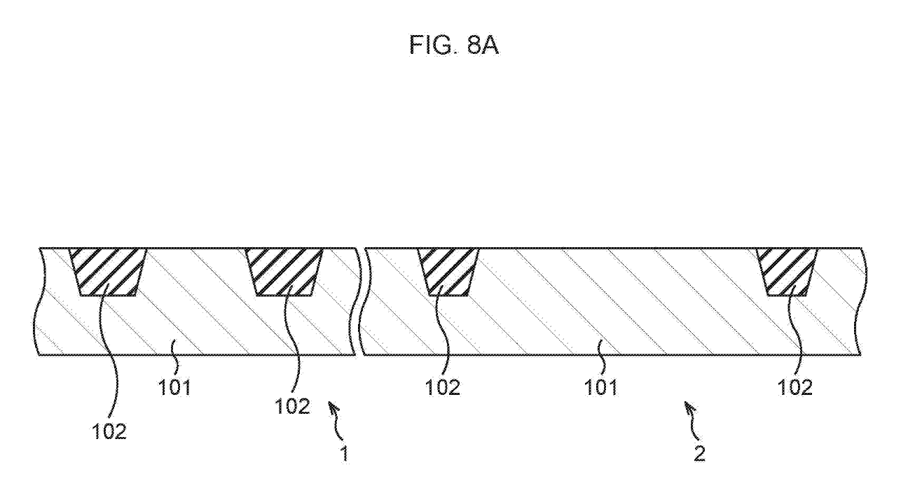

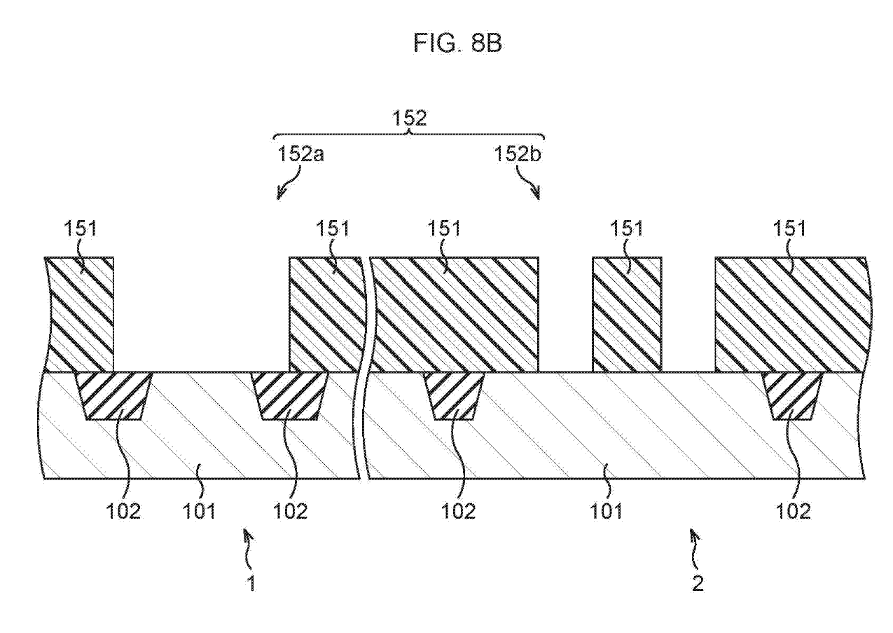

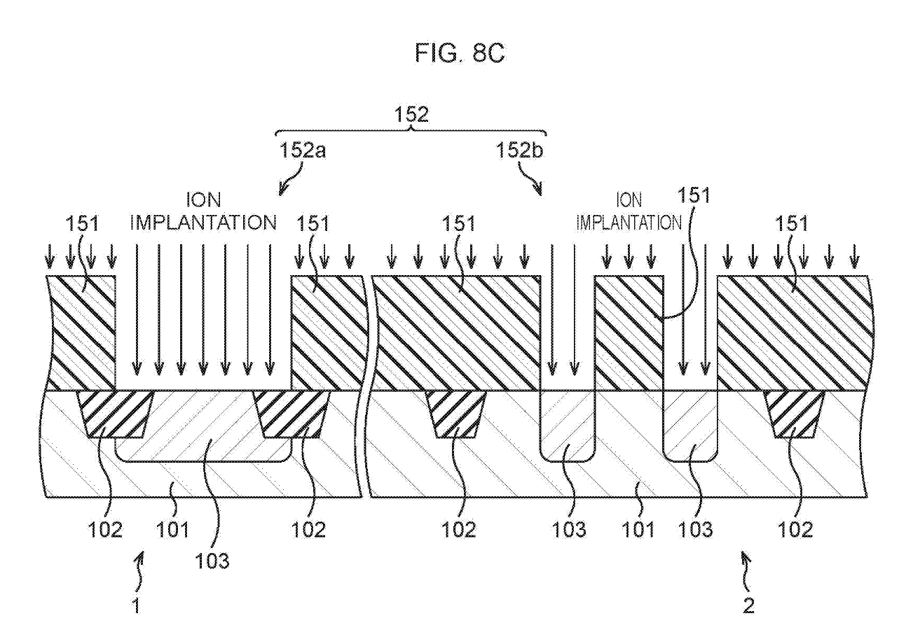

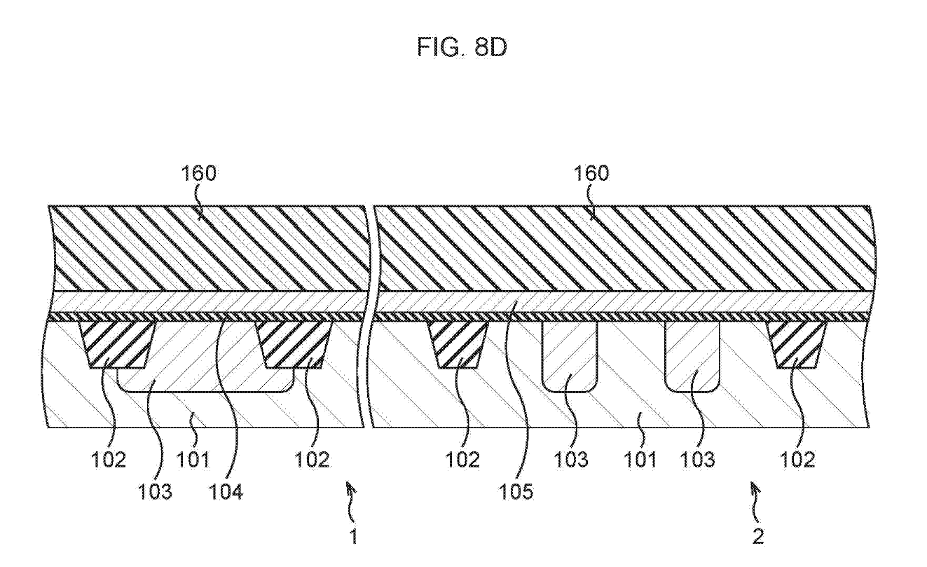

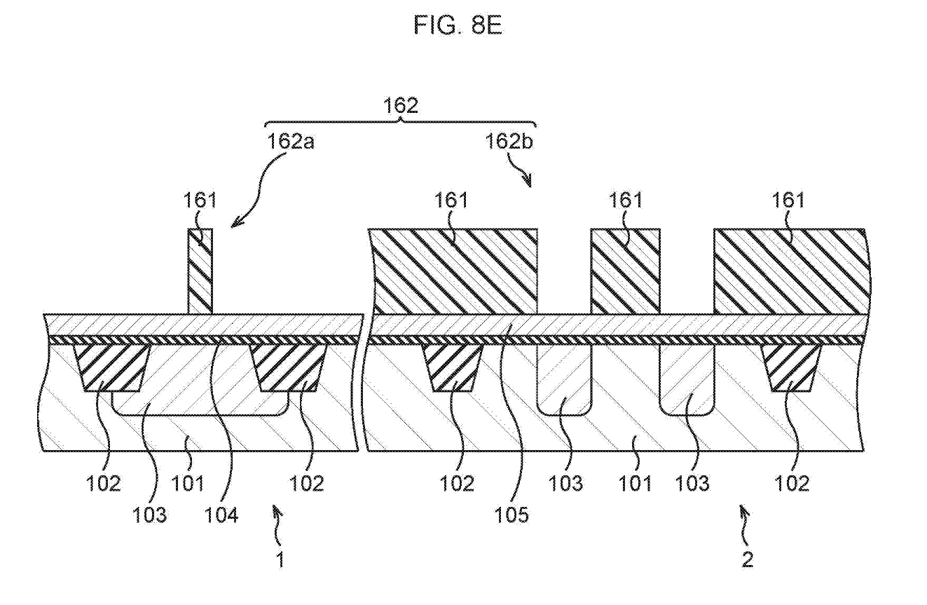

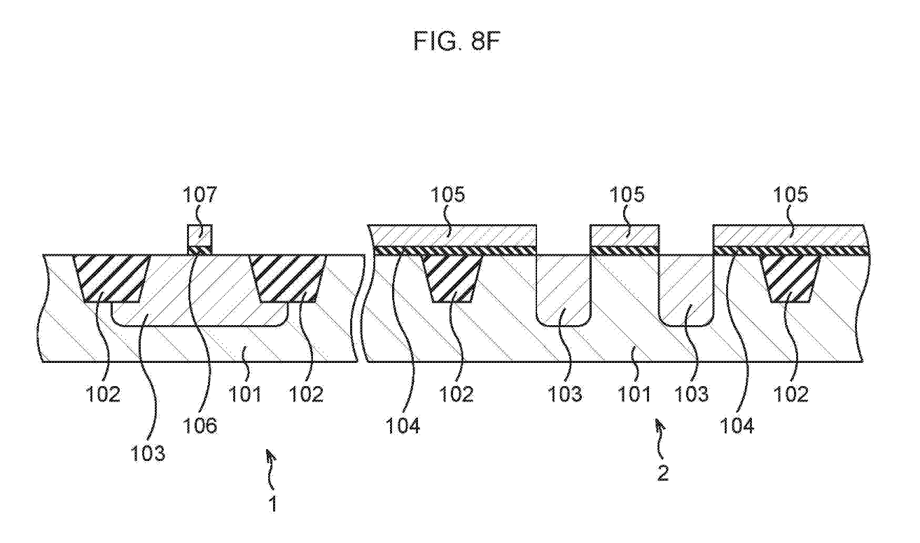

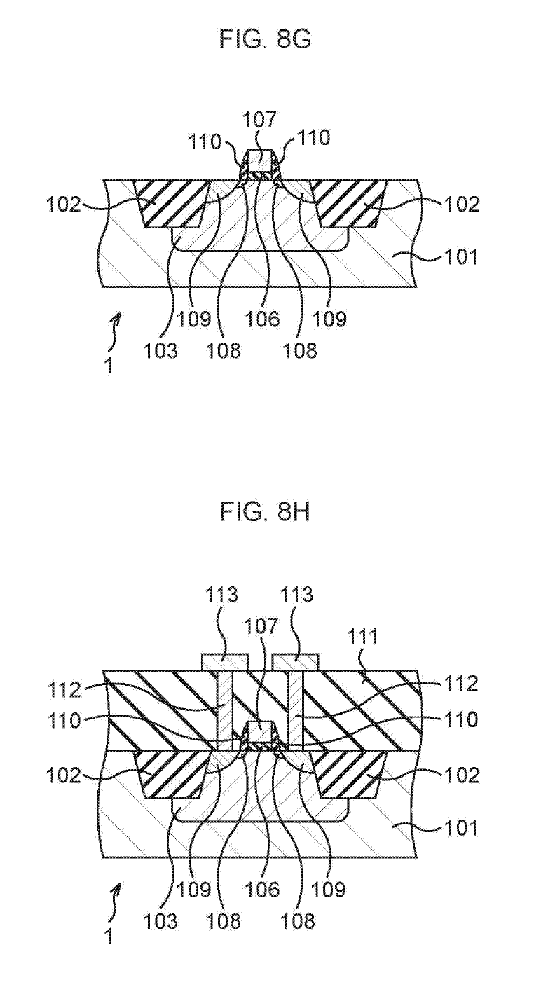

Next, a second embodiment will be described. In the second embodiment, a field-effect transistor is formed. FIG. 8A to FIG. 8H are cross-sectional views illustrating a method of manufacturing a semiconductor device according to the second embodiment in the order of steps.

In the second embodiment, as illustrated in FIG. 8A, an element isolation region 102 is formed in a surface of a substrate 101 such as a silicon substrate. The element isolation region 102 is formed in device regions 1 where actual devices are to be formed and in a scribe region 2 between the device regions 1. In the formation of the element isolation region 102, for example, a mask with a pattern exposing a region where the element isolation region 102 is to be formed is formed on the substrate 101, and the substrate 101 is etched using the mask to form trenches in the surface of the substrate 101, and an insulating film is formed in the trenches.

Then, as illustrated in FIG. 8B, a mask 151 with a pattern 152 is formed on the substrate 101. The pattern 152 includes a pattern 152a for well in the device region 1 and a pattern 152b for positional deviation inspection in the scribe region 2. In the formation of the mask 151, for example, a photoresist film with a thickness of 0.3 μm to 2.0 μm is formed, and exposure and development of the photoresist film are performed so as to form the pattern 152. For example, the width of an opening portion of the pattern 152a is 0.15 μm to 1.0 μm, and the width of an opening portion of the pattern 152b is 1 μm to 3 μm. Thereafter, the positional deviation OVL_1-2 of the position of the pattern 152b from the position of the element isolation region 102 is measured in the scribe region 2.

Subsequently, as illustrated in FIG. 8C, ion implantation of impurities is performed using the mask 151 so as to form impurity-implanted regions 103 in the surface of the substrate 101.

Then, as illustrated in FIG. 8D, the mask 151 is removed. Thereafter, an insulating film 104 and a polycrystalline silicon film 105 are formed on the substrate 101. For example, a silicon oxide film is formed by thermal oxidation as the insulating film 104, and the thickness of the polycrystalline silicon film 105 is 100 nm to 150 nm. Subsequently, a photoresist film 160 with a thickness of 100 nm to 300 nm is formed on the polycrystalline silicon film 105.

Then, as illustrated in FIG. 8E, exposure and development of the photoresist film 160 are performed so as to form a pattern 162. The pattern 162 includes a pattern 162a for gate electrode in the device region 1 and a pattern 162b for positional deviation inspection in the scribe region 2. For example, the width of a covering portion of the pattern 162a is 50 nm to 100 nm, and the width of an opening portion of the pattern 162b is 1 μm to 3 μm.

In the formation of the pattern 162, the parameter obtained by adding the parameter reflecting the positional deviation OVL_1-2 to the adjustment parameter A₀ for aligning the position of the pattern 162b with the position of the element isolation region 102 in the scribe region 2 is set as the adjustment parameter A in the exposure apparatus (Step S21). For example, the parameter obtained by adding the product of the positional deviation OVL_1-2 and the correction coefficient h (0≦h≦1) to the adjustment parameter A₀ is used as the adjustment parameter A. Thereafter, exposure using the exposure apparatus is performed so as to transfer the pattern of the photomask to the photoresist film 160, and the photoresist film 160 is developed (Step S22).

Alignment using the adjustment parameter A is performed in the exposure. This alignment is performed, for example, by the function provided in the exposure apparatus. After development, the positional deviation OVL_1-3 of the position of the pattern 162b from the position of the element isolation region 102 is measured (Step S23), and the positional deviation OVL_1-3 is judged (Step S24). Then, if the positional deviation OVL_1-3 does not fall within an allowable range, the adjustment parameter A is changed (Step S25). In the change of the adjustment parameter A, the parameter obtained by subtracting the positional deviation OVL_1-3 from the adjustment parameter A before change is used as the adjustment parameter A after change. Then, a mask 161 is formed again. The newly formed mask corresponds to a fourth mask with a fourth pattern.

If the positional deviation OVL_1-3 falls within the allowable range, the polycrystalline silicon film 105 and the insulating film 104 are etched using the mask 161 as illustrated in FIG. 8F, thereby a gate insulating film 106 and a gate electrode 107 are formed in the device region 1. Then, the mask 161 is removed.

Then, as illustrated in FIG. 8G, impurity implanted regions 108 are formed in the surface in the impurity-implanted region 103, side walls 110 are formed on side surfaces of the gate electrode 107, and impurity implanted regions 109 are formed deeper than the impurity implanted regions 108 in the surface in the impurity-implanted region 103 in the device region 1. In this manner, a field-effect transistor is formed. It is preferable to use masks also for forming the impurity implanted regions 108 and for forming the impurity implanted regions 109, and to apply the same method as that in the first embodiment for alignment of patterns formed in the masks.

Thereafter, as illustrated in FIG. 8H, an interlayer insulating film 111 covering the field-effect transistor is formed on the substrate 101, conductive plugs 112 are formed in the interlayer insulating film 111, and wirings 113 in contact with the conductive plugs 112 are formed on the interlayer insulating film 111. It is preferable to use masks also for forming opening portions for the conductive plugs 112 and forming the wirings 113, and to apply the same method as that in the first embodiment for alignment of patterns formed in the masks.

Subsequently, an interlayer insulating film, wirings and others are formed in upper layers to complete a semiconductor device.

According to the second embodiment, it is possible to accurately align the gate electrode 107 with the element isolation regions 102 and the impurity-implanted region 103 even though the impurity-implanted region 103 cannot be optically detected.

### Third Embodiment

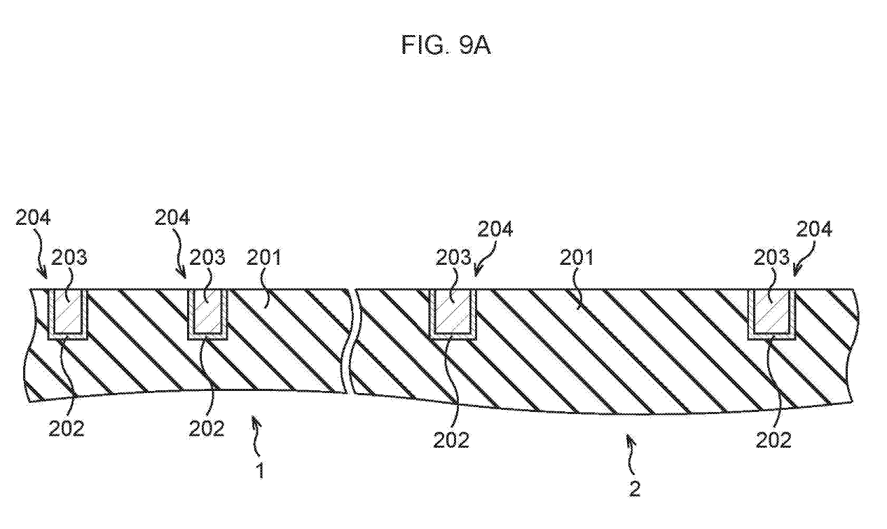

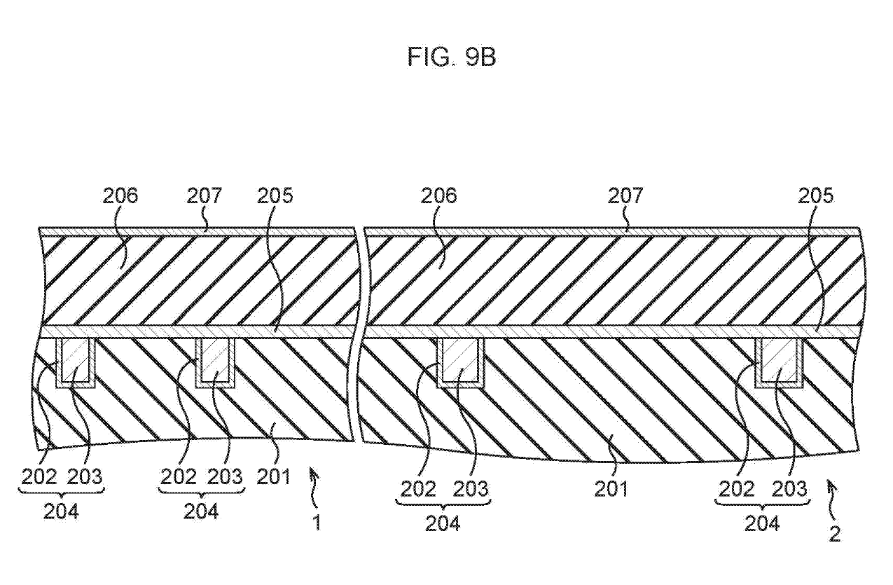

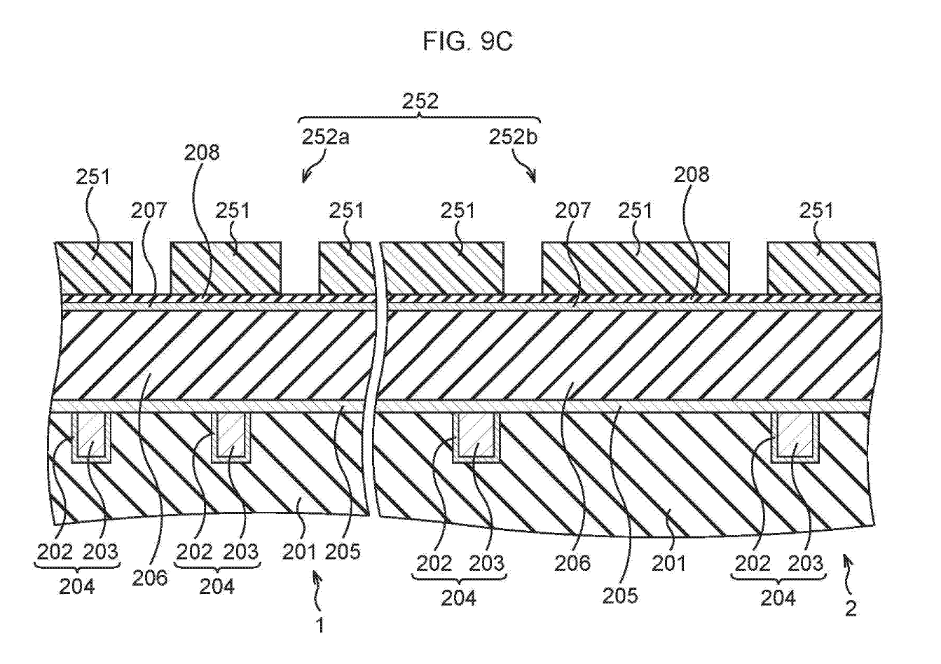

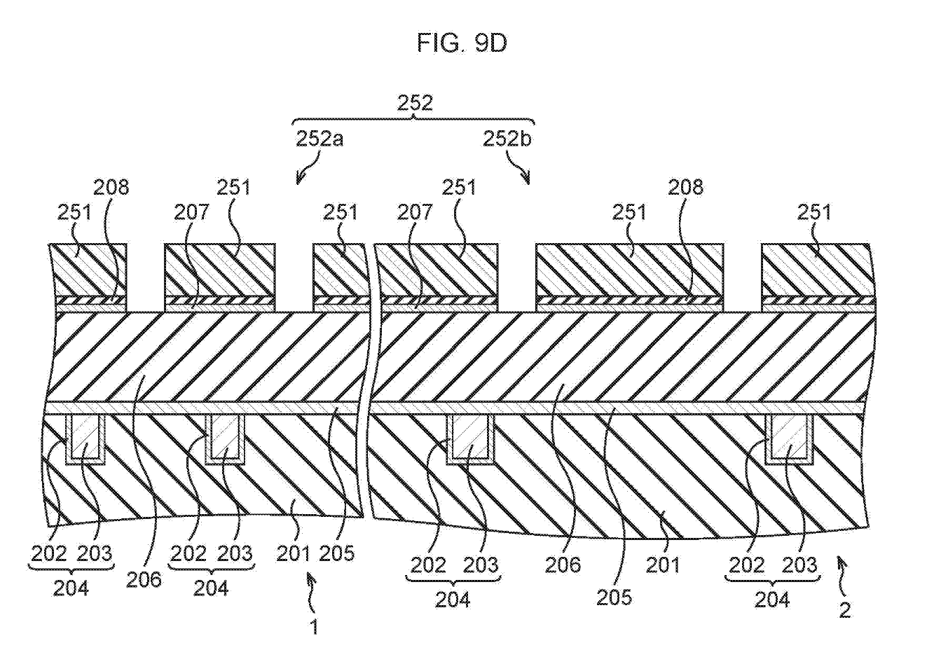

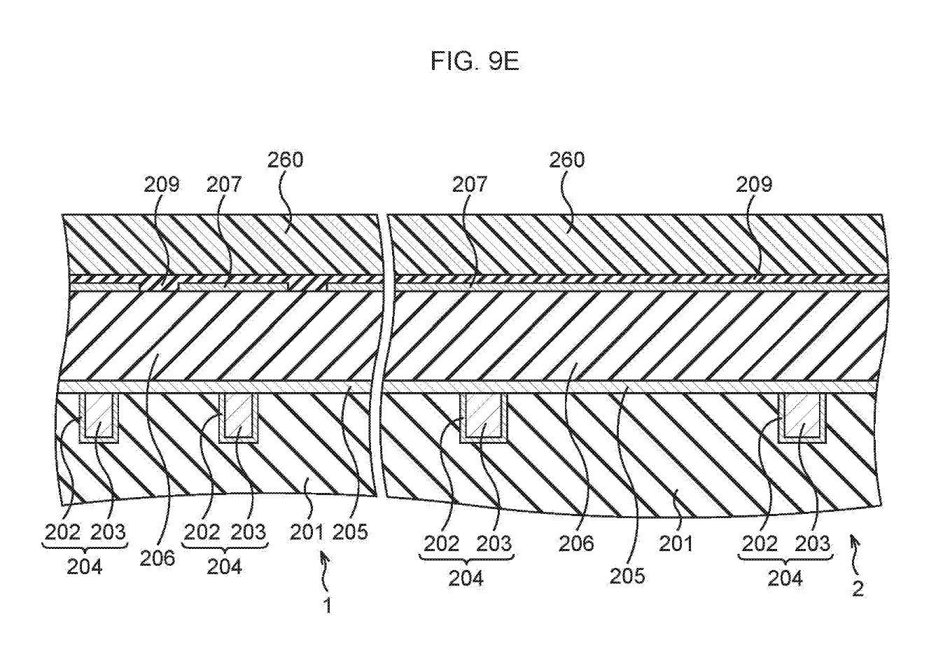

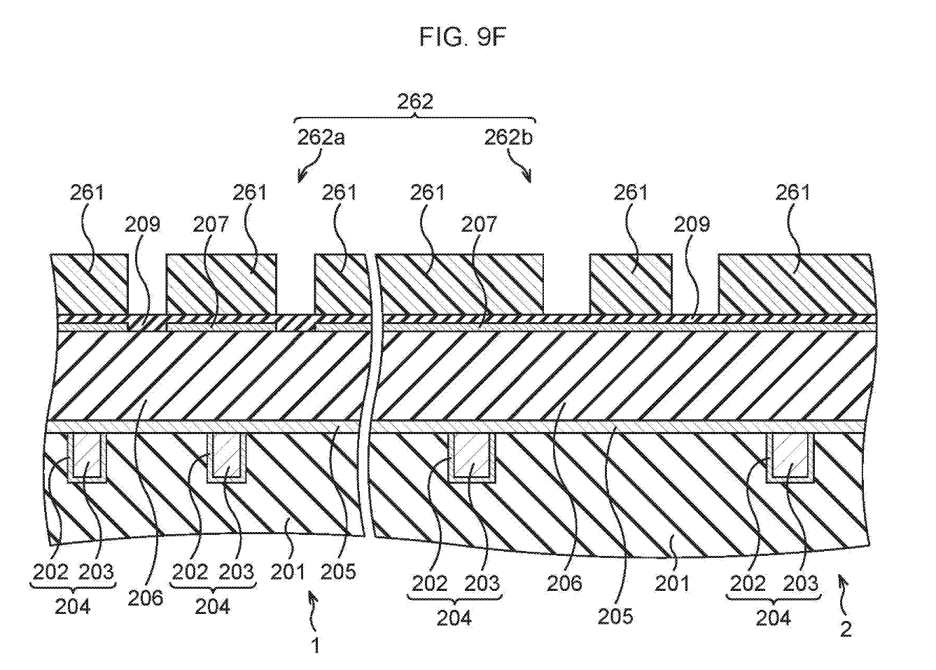

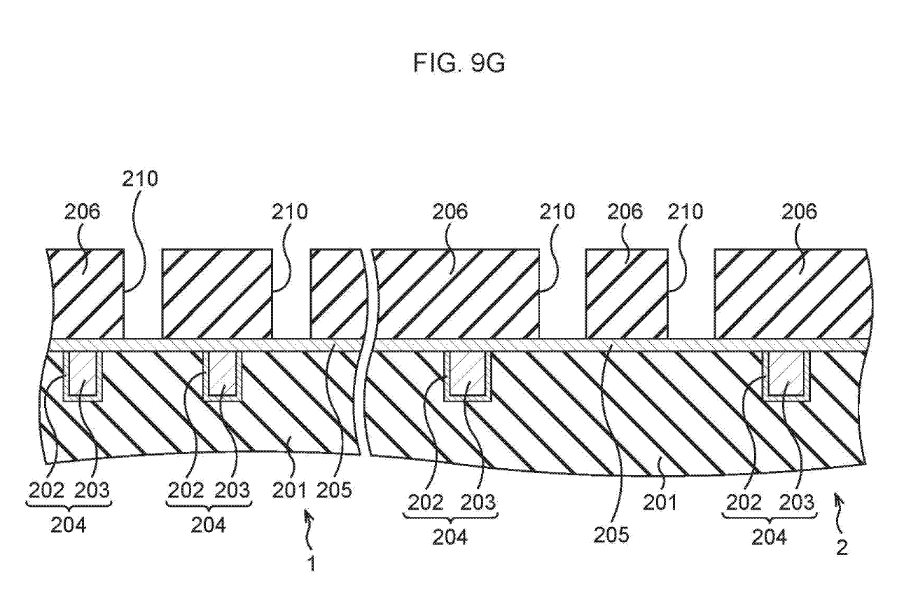

Next, a third embodiment will be described. In the third embodiment, wirings are formed by dual damascene method. FIG. 9A to FIG. 9G are cross-sectional views illustrating a method of manufacturing a semiconductor device according to the third embodiment in the order of steps.

In the third embodiment, first, wirings 204 each including a tantalum film (Ta film) 202 and a copper film (Cu film) 203 are formed in the surface of a silicon oxynitride film (SiOC film) 201. The wirings 204 are connected to field-effect transistors or others below the SiOC film 201. The wirings 204 are formed in the device regions 1 where the actual devices are to be formed and in the scribe region 2 between the device regions 1. In the formation of the wirings 204, for example, a mask with a pattern exposing regions where the wirings are to be formed is formed on the SiOC film 201, and the SiOC film 201 is etched using the mask so as to form wiring trenches in the surface of the SiOC film 201, and the Ta film 202 and the Cu film 203 are formed in each of the wiring trenches.

Then, as illustrated in FIG. 9B, a silicon carbide film (SiC film) 205, a SiOC film 206, and a titanium nitride film (TiN film) 207 are formed on the SiOC film 201. The thicknesses of the SiC film 205, the SiOC film 206, and the TiN film 207 are, for example, 20 nm to 50 nm, 200 nm to 400 nm, and 5 nm to 25 nm, respectively.

Thereafter, as illustrated in FIG. 9C, an anti-reflection film 208 is formed on the TiN film 207, and a mask 251 with a pattern 252 is formed on the anti-reflection film 208. The thickness of the anti-reflection film 208 is, for example, 50 nm to 150 nm. The pattern 252 includes a pattern 252a for wiring trench in the device region 1 and a pattern 252b for positional deviation inspection in the scribe region 2. In the formation of the mask 251, for example, a photoresist film with a thickness of 100 nm to 200 nm is formed, and exposure and development of the photoresist film are performed so as to form the pattern 252. For example, the width of an opening portion of the pattern 252a is 70 nm to 120 nm, and the width of an opening portion of the pattern 252b is 1 μm to 3 μm. Subsequently, the positional deviation OVL_1-2 of the position of the pattern 252b from the position of the wiring 204 is measured in the scribe region 2.

Then, as illustrated in FIG. 9D, the anti-reflection film 208 and the TiN film 207 are etched using the mask 251 so as to form a pattern for wiring trench in the TiN film 207.

Thereafter, as illustrated in FIG. 9E, the mask 251 and the anti-reflection film 208 are removed. Subsequently, an anti-reflection film 209 is formed on the TiN film 207. The thickness of the anti-reflection film 209 is, for example, 50 nm to 150 nm. Subsequently, a photoresist film 260 with a thickness of 100 nm to 200 nm is formed on the anti-reflection film 209. The portion of the scribe region 2 in FIG. 9A to FIG. 9D is located in an inspection mark arrangement region 3 in FIG. 9H, and the portion of the scribe region 2 in FIG. 9E to FIG. 9G is located in an inspection mark arrangement region 4 away from the inspection mark arrangement region 3 in FIG. 9H.

Thereafter, as illustrated in FIG. 9F, exposure and development of the photoresist film 260 are performed so as to form a pattern 262. The pattern 262 includes a pattern 262a for via hole in the device region 1 and a pattern 262b for positional deviation inspection in the scribe region 2. As illustrated in FIG. 9H, the pattern 252b is formed in the inspection mark arrangement region 3, whereas the pattern 262b is formed in the inspection mark arrangement region 4. For example, the width of an opening portion of the pattern 262a is 70 nm to 120 nm, and the width of an opening portion of the pattern 262b is 1 μm to 3 μm.

In the formation of the pattern 262, the parameter A obtained by adding the parameter reflecting the positional deviation OVL_1-2 to the adjustment parameter A₀ for aligning the pattern 262b with the position of the wiring 204 in the scribe region 2 is set in the exposure apparatus (Step S21). For example, the parameter obtained by adding the product of the positional deviation OVL_1-2 and the correction coefficient h (0≦h≦1) to the adjustment parameter A₀ is used as the adjustment parameter A. Thereafter, exposure using the exposure apparatus is performed so as to transfer the pattern of the photomask to the photoresist film 260, and the photoresist film 260 is developed (Step S22). Alignment with the wiring 204 using the adjustment parameter A is performed in the exposure. This alignment is performed, for example, by the function provided in the exposure apparatus. Subsequently, the positional deviation OVL_1-3 of the position of the pattern 262b from the position of the wiring 204 is measured (Step S23), and the positional deviation OVL_1-3 is judged (Step S24). Then, if the positional deviation OVL_1-3 does not fall within an allowable range, the adjustment parameter A is changed (Step S25). In the change of the adjustment parameter A, the parameter obtained by subtracting the positional deviation OVL_1-3 from the adjustment parameter A before change is used as the adjustment parameter A after change. Then, a mask 261 is formed again.

If the positional deviation OVL_1-3 falls within the allowable range, the anti-reflection film 209 and the SiOC film 206 are etched using the mask 261 as illustrated in FIG. 9G, thereby via holes 210 are formed together with the wiring trenches. Then, the mask 261 is removed.

Thereafter, via plugs, wirings and others are formed to complete a semiconductor device.

According to the third embodiment, it is possible to accurately align the via hole 210 with the wiring trench in the SiOC film 206 and the wiring 204 even though the TiN film 207 used as a hard mask is as thin as 5 nm to 25 nm and the contrast of the pattern of the wiring trench formed therein is low.

### Fourth Embodiment

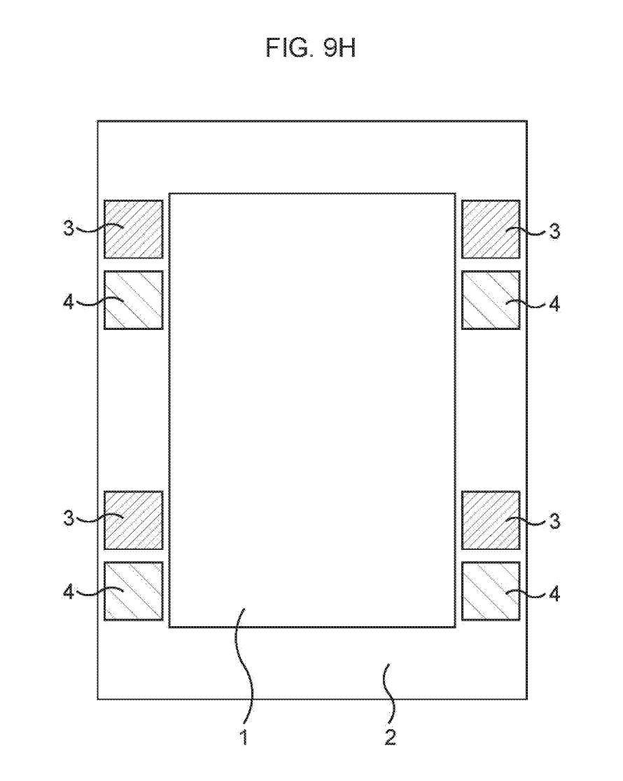

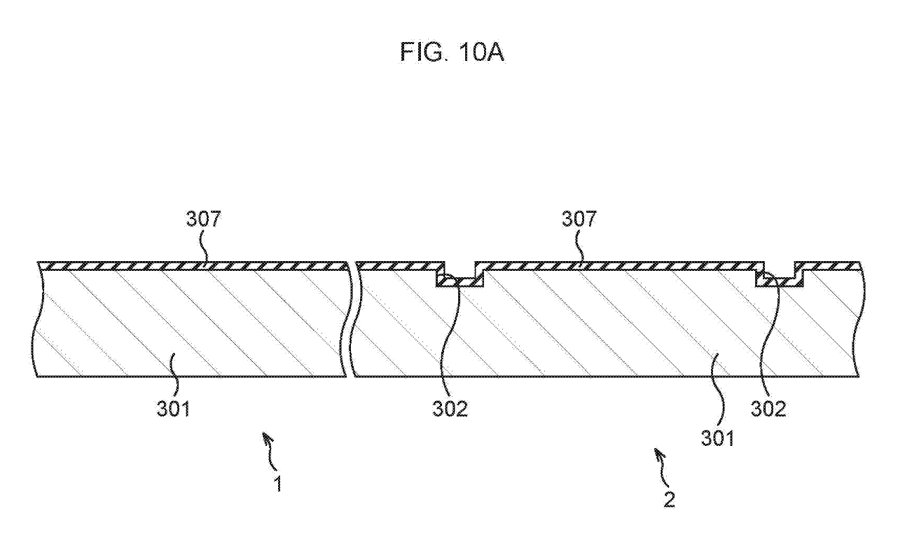

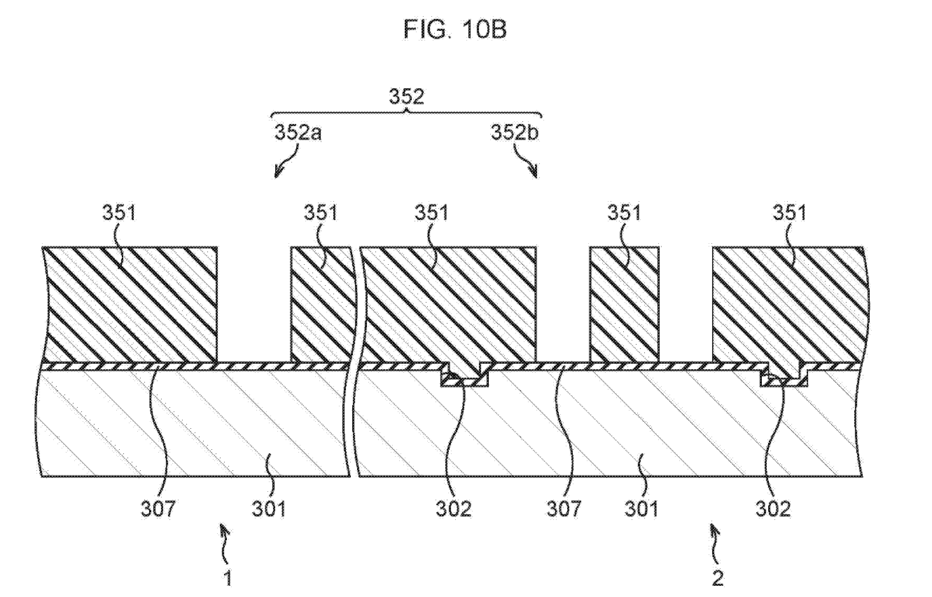

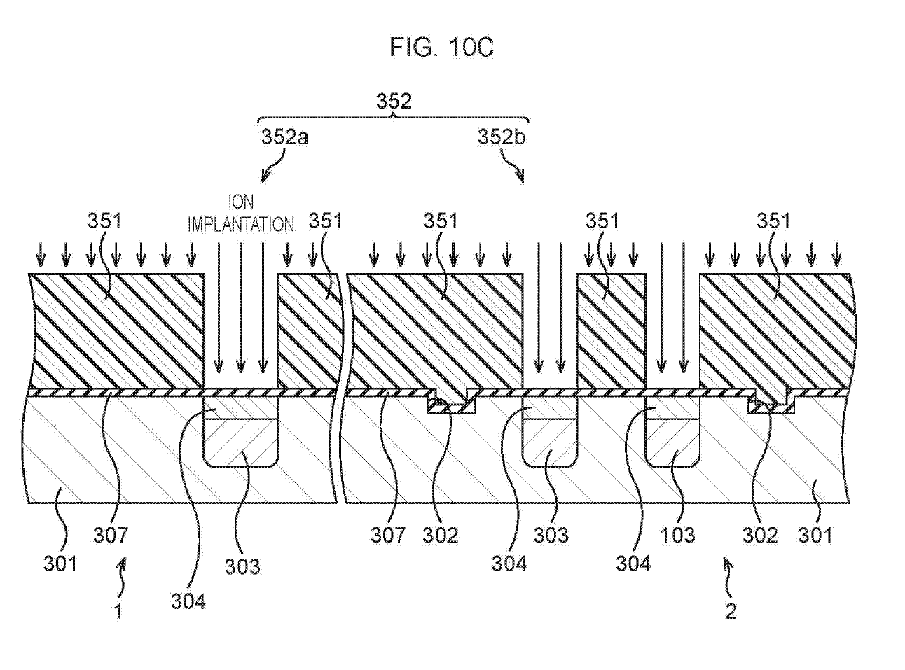

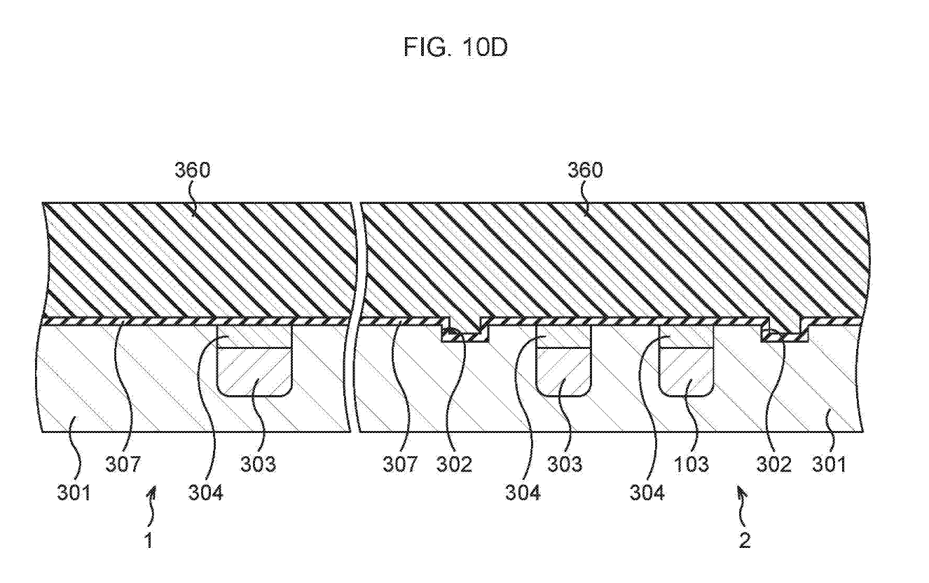

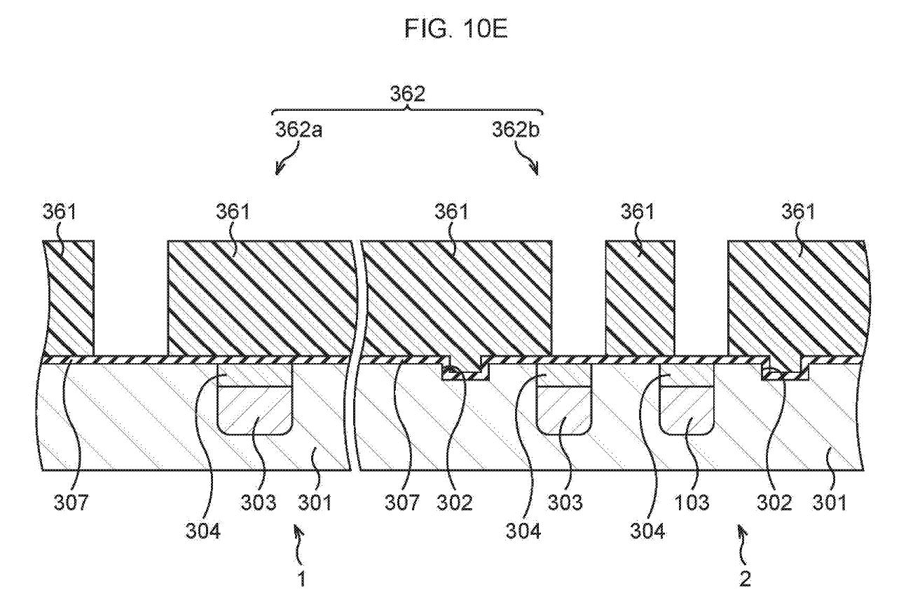

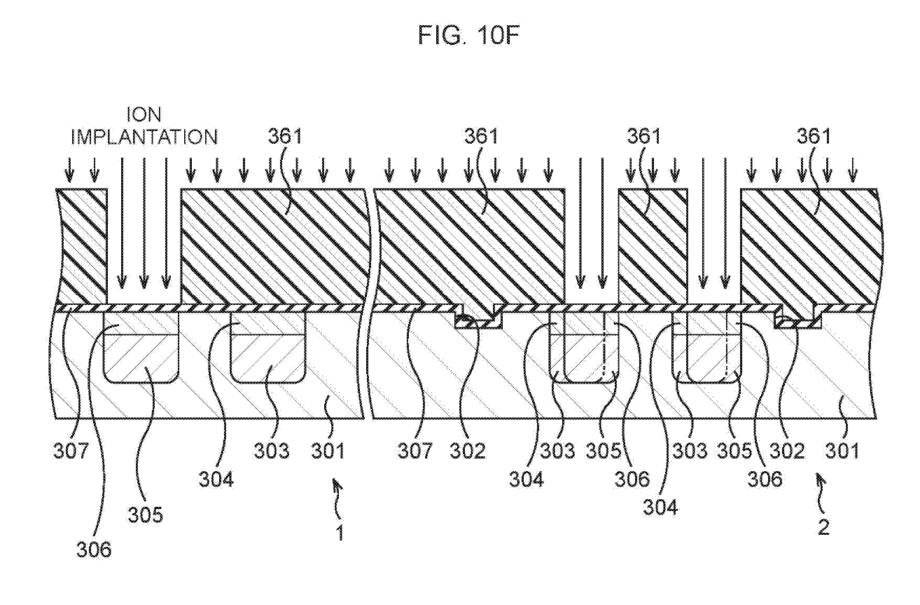

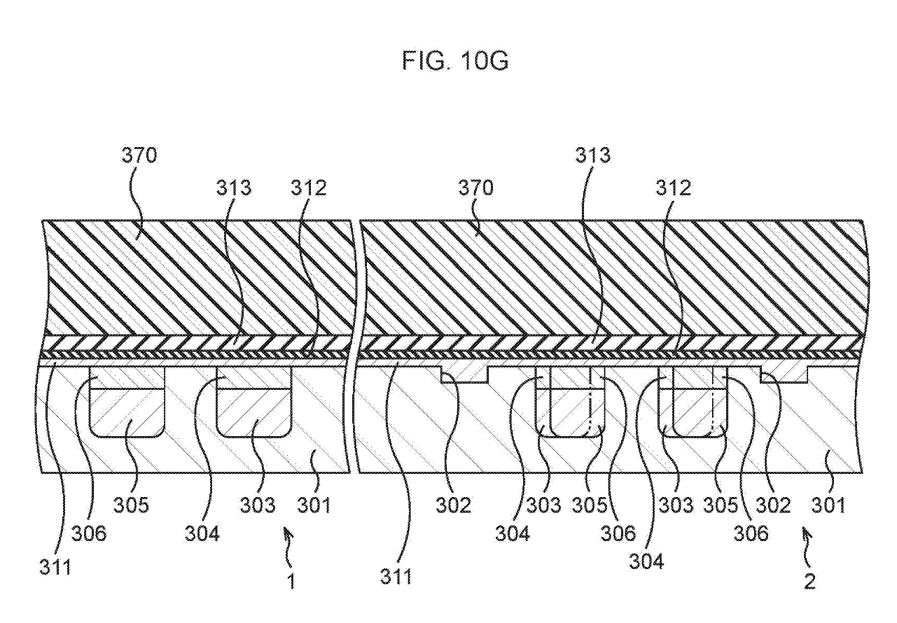

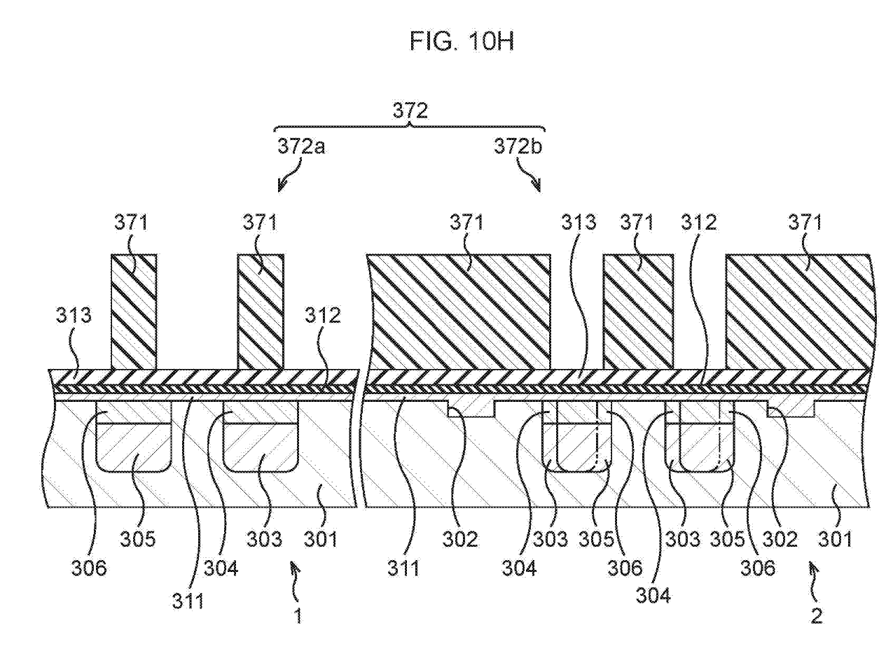

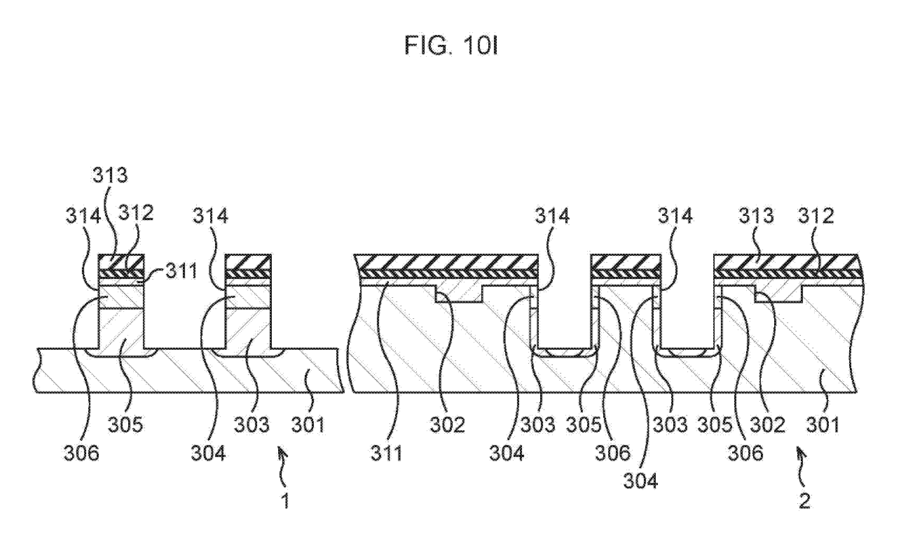

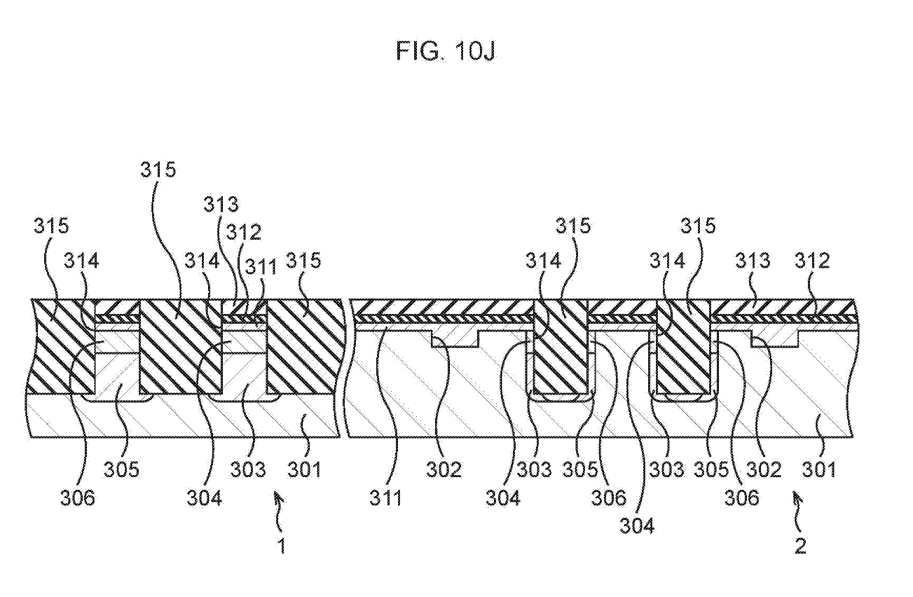

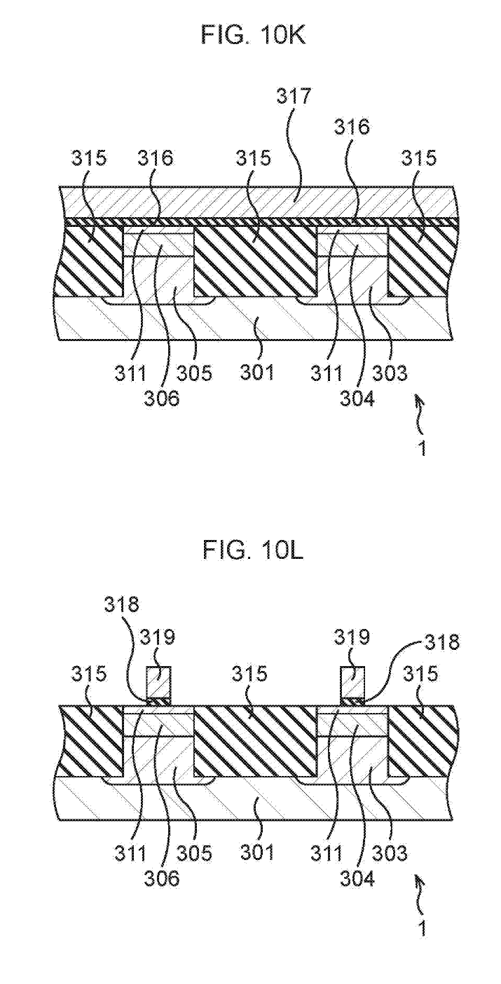

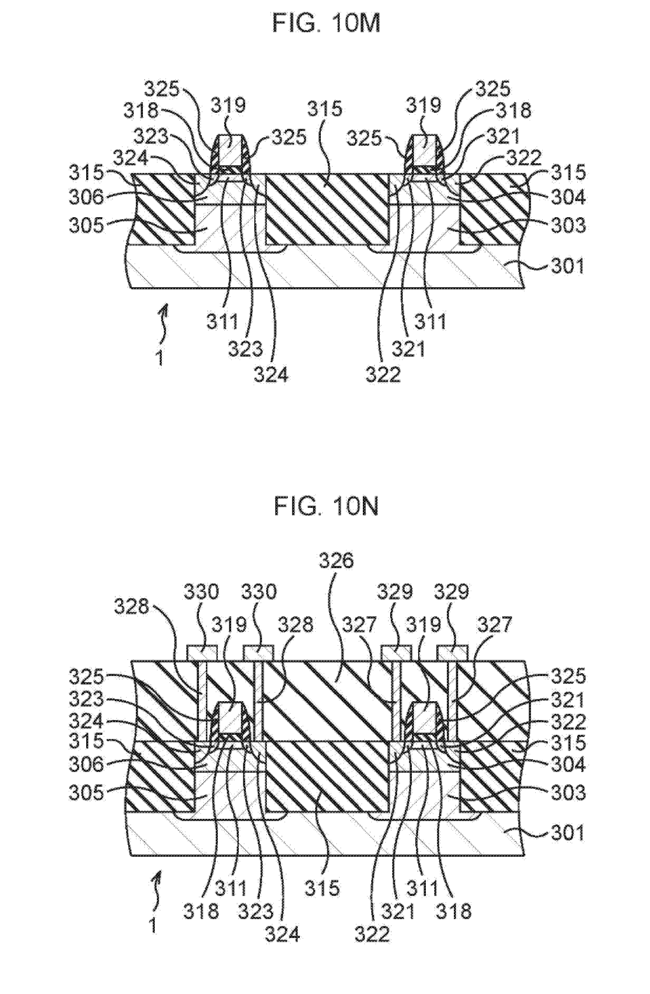

Next, a fourth embodiment will be described. In the fourth embodiment, an N-type field-effect transistor and a P-type field-effect transistor extremely low in impurity concentration of channel are formed. The field-effect transistor extremely low in impurity concentration of channel is sometimes called a DDC (deeply depleted channel) transistor. FIG. 10A to FIG. 10N are cross-sectional views illustrating a method of manufacturing a semiconductor device according to the fourth embodiment in the order of steps.

In the fourth embodiment, as illustrated in FIG. 10A, patterns 302 for positional deviation inspection marks are formed in a scribe region 2 of a substrate 301 such as a silicon substrate. In the formation of the patterns 302, for example, a mask with a pattern exposing regions where the patterns 302 are to be formed is formed on the substrate 301, and the substrate 301 is etched using the mask so as to form trenches in the surface of the substrate 301. Subsequently, a silicon oxide film 307 is formed as a protective film on the surface of the substrate 301 on the patterns 302 side. The silicon oxide film 307 may be formed, for example, by thermal oxidation.

Thereafter, as illustrated in FIG. 10B, a mask 351 with a pattern 352 is formed on the substrate 301. The pattern 352 includes a pattern 352a for P-well in the device region 1 and a pattern 352b for positional deviation inspection in the scribe region 2. In the formation of the mask 351, for example, a photoresist film with a thickness of 1.0 μm to 3.0 μm is formed, and exposure and development of the photoresist film are performed so as to form the pattern 352. For example, the width of an opening portion of the pattern 352a is 0.15 μm to 2.0 μm, and the width of an opening portion of the pattern 352b is 1 μm to 3 μm. Thereafter, the positional deviation OVL_1-2 of the position of the pattern 352b from the position of the pattern 302 is measured in the scribe region 2.

Subsequently, as illustrated in FIG. 10C, ion implantation of P-type impurities is performed using the mask 351 so as to form P-type impurity-implanted regions 303 in the surface of the substrate 301. Further, ion implantation of P-type impurities is performed using the mask 351 so as to form P-type impurity-implanted regions 304 shallower than the impurity-implanted regions 303 in the surface of the substrate 301.

Then, as illustrated in FIG. 10D, the mask 351 is removed. Thereafter, a photoresist film 360 with a thickness of 1.0 μm to 3.0 μm is formed on the silicon oxide film 307.

Subsequently, as illustrated in FIG. 10E, exposure and development of the photoresist film 360 are performed so as to form a pattern 362. The pattern 362 includes a pattern 362a for N-well in the device region 1 and a pattern 362b for positional deviation inspection in the scribe region 2. For example, the width of an opening portion of the pattern 362a is 0.15 μm to 2.0 μm, and the width of an opening portion of the pattern 362b is 1 μm to 3 μm.

In the formation of the pattern 362, the parameter obtained by adding the parameter reflecting the positional deviation OVL_1-2 to the adjustment parameter A₀ for aligning the position of the pattern 362b with the position of the pattern 302 in the scribe region 2 is set as an adjustment parameter A₁ in the exposure apparatus (Step S21). For example, a parameter obtained by adding a product of the positional deviation OVL_1-2 and a correction coefficient h₁ (0≦h₁≦1) to the adjustment parameter A₀ is used as the adjustment parameter A₁. Thereafter, exposure using the exposure apparatus is performed so as to transfer the pattern of the photomask to the photoresist film 360, and the photoresist film 360 is developed (Step S22). Alignment with the pattern 302 using the adjustment parameter A₁ is performed in the exposure. This alignment is performed, for example, by the function provided in the exposure apparatus. After development, the positional deviation OVL_1-3 of the position of the pattern 362b from the position of the pattern 302 is measured (Step S23), and the positional deviation OVL_1-3 is judged (Step S24). Then, if the positional deviation OVL_1-3 does not fall within an allowable range, the adjustment parameter A₁ is changed (Step S25). In the change of the adjustment parameter A₁, a parameter obtained by subtracting the positional deviation OVL_1-3 from the adjustment parameter A₁ before change is used as an adjustment parameter A₁ after change. Then, a mask 361 is formed again.

If the positional deviation OVL_1-3 falls within the allowable range, ion implantation of N-type impurities is performed using the mask 361 so as to form N-type impurity-implanted regions 305 in the surface of the substrate 301 as illustrated in FIG. 10F. Further, ion implantation of N-type impurities is performed using the mask 361 so as to form N-type impurity-implanted regions 306 shallower than the impurity-implanted regions 305 in the surface of the substrate 301.

Subsequently, as illustrated in FIG. 10G, the mask 361 is removed. Thereafter, the silicon oxide film 307 is removed, and a silicon film 311, a silicon oxide film 312, and a silicon nitride film 313 are formed on the substrate 301. For example, the thickness of the silicon film 311 is 20 nm to 50 nm, the thickness of the silicon oxide film 312 is 3 nm to 10 nm, and the thickness of the silicon nitride film 313 is 50 nm to 150 nm. Subsequently, a photoresist film 370 with a thickness of 100 nm to 300 nm is formed on the silicon nitride film 313.

Then, as illustrated in FIG. 10H, exposure and development of the photoresist film 370 are performed so as to form a pattern 372. The pattern 372 includes a pattern 372a for element isolation region in the device region 1 and a pattern 372b for positional deviation inspection in the scribe region 2. For example, the width of an opening portion of the pattern 372a is 100 nm to 300 nm, and the width of an opening portion of the pattern 372b is 1 μm to 3 μm.

In the formation of the pattern 372, the parameter obtained by adding the parameter reflecting the positional deviation OVL_1-2 and the positional deviation OVL_1-3 to the adjustment parameter A₀ for aligning the position of the pattern 372b with the position of the pattern 302 in the scribe region 2 is set as an adjustment parameter A₂ in the exposure apparatus. For example, a parameter obtained by adding a product of the positional deviation OVL_1-2 and a correction coefficient h₁ (0≦h₁≦1) and a product of the positional deviation OVL_1-3 and a correction coefficient h₂ (0≦h₂≦1, h₁+h₂=1) to the adjustment parameter A₀ is used as the adjustment parameter A₂. Thereafter, exposure using the exposure apparatus is performed so as to transfer the pattern of the photomask to the photoresist film 370, and the photoresist film 370 is developed. Alignment using the adjustment parameter A₂ is performed in the exposure. This alignment is performed, for example, by the function provided in the exposure apparatus. Subsequently, a positional deviation OVL_1-4 of the position of the pattern 372b from the position of the pattern 302 is measured, and the positional deviation OVL_1-4 is judged. Then, if the positional deviation OVL_1-4 does not fall within an allowable range, the adjustment parameter A₂ is changed (Step S25). In the change of the adjustment parameter A₂, a parameter obtained by subtracting the positional deviation OVL_1-4 from the adjustment parameter A₂ before change is used as an adjustment parameter A₂ after change. Then, a mask 371 is formed again.

If the positional deviation OVL_1-4 falls within the allowable range, the silicon nitride film 313, the silicon oxide film 312, the silicon film 311, and the substrate 301 are etched using the mask 371 to form trenches 314 for element isolation in the device region 1 as illustrated in FIG. 10I. Then, the mask 371 is removed.

Subsequently, as illustrated in FIG. 10J, an insulating film 315 for element isolation is formed in the trenches 314. In the formation of the insulating films 315, for example, a silicon film is formed by thermal oxidation, a silicon oxide film is then formed by high-density plasma chemical vapor deposition (CVD) method, and chemical mechanical polishing (CMP) is performed.

Thereafter, as illustrated in FIG. 10K, the silicon nitride film 313 and the silicon oxide film 312 are removed, and an insulating film 316 and a polycrystalline silicon film 317 are formed on the silicon film 311. As the insulating film 316, for example, a silicon oxide film is formed by thermal oxidation.

Subsequently, as illustrated in FIG. 10L, the polycrystalline silicon film 317 and the insulating film 316 are etched, thereby gate insulating films 318 and gate electrodes 319 are formed in the device region 1. It is preferable to use a mask also for etching the polycrystalline silicon film 317 and the insulating film 316, and to apply the same method as that in the first embodiment for alignment of a pattern formed in the mask. For example, it is preferable to perform alignment in consideration of the positional deviation OVL_1-2, the positional deviation OVL_1-3, or the positional deviation OVL_1-4, or any combination thereof.

Then, as illustrated in FIG. 10M, N-type impurity implanted regions 321 are formed in the P-type impurity implanted region 304 and the silicon film 311 thereon, and P-type impurity implanted regions 323 are formed in the N-type impurity-implanted region 306 and the silicon film 311 thereon in the device region 1. Thereafter, side walls 325 are formed on side surfaces of the gate electrodes 319. Subsequently, N-type impurity implanted regions 322 are formed deeper than the impurity implanted regions 321 in the P-type impurity implanted region 304 and the silicon film 311 thereon, and P-type impurity implanted regions 324 are formed deeper than the impurity implanted regions 323 in the N-type impurity-implanted region 306 and the silicon film 311 thereon. In this manner, an N-type field-effect transistor and a P-type field-effect transistor are formed. It is preferable to use masks also for forming the impurity implanted regions 321 to 324, and to apply the same method as that in the first embodiment for alignment of patterns formed in the masks.

Then, as illustrated in FIG. 10N, an interlayer insulating film 326 covering the N-type field-effect transistor and the P-type field-effect transistor is formed on the substrate 301.

Thereafter, conductive plugs 327 connected to the impurity implanted regions 322 and conductive plugs 328 connected to the impurity implanted regions 324 are formed in the interlayer insulating film 326. Subsequently, wirings 329 connected to the conductive plugs 327 and wirings 330 connected to the conductive plugs 328 are formed on the interlayer insulating film 326. It is preferable to use masks also for forming opening portions for the conductive plugs 327 and 328 and for forming the wirings 320 and 330, and to apply the same method as that in the first embodiment for alignment of patterns formed in the masks.

Thereafter, an interlayer insulating film, wirings and others are formed in upper layers to complete a semiconductor device.

According to the fourth embodiment, it is possible to accurately align the trenches 314 for element isolation with the impurity implanted regions 303 to 306 even though the P-type impurity implanted regions 303 and 304 and the N-type impurity-implanted regions 305 and 306 cannot be optically detected.

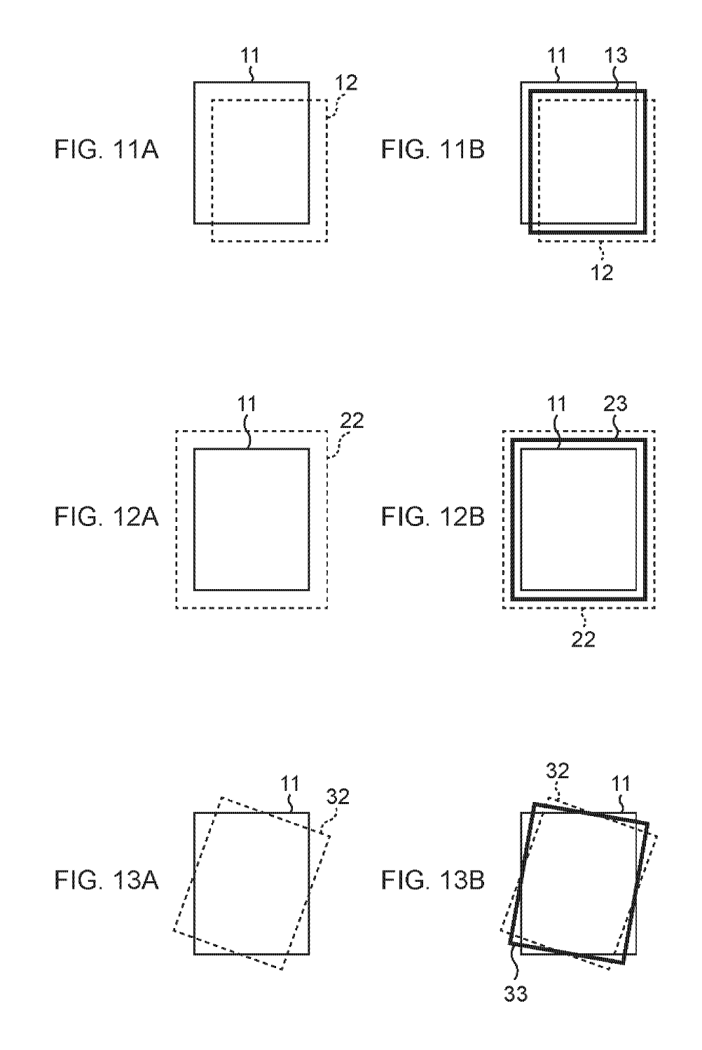

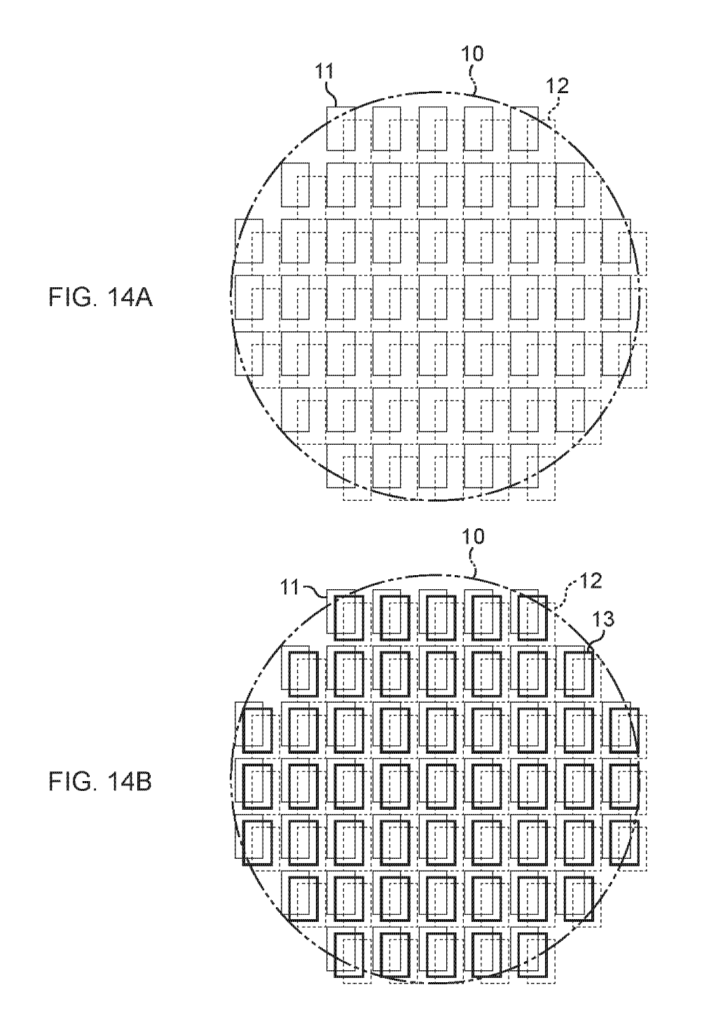

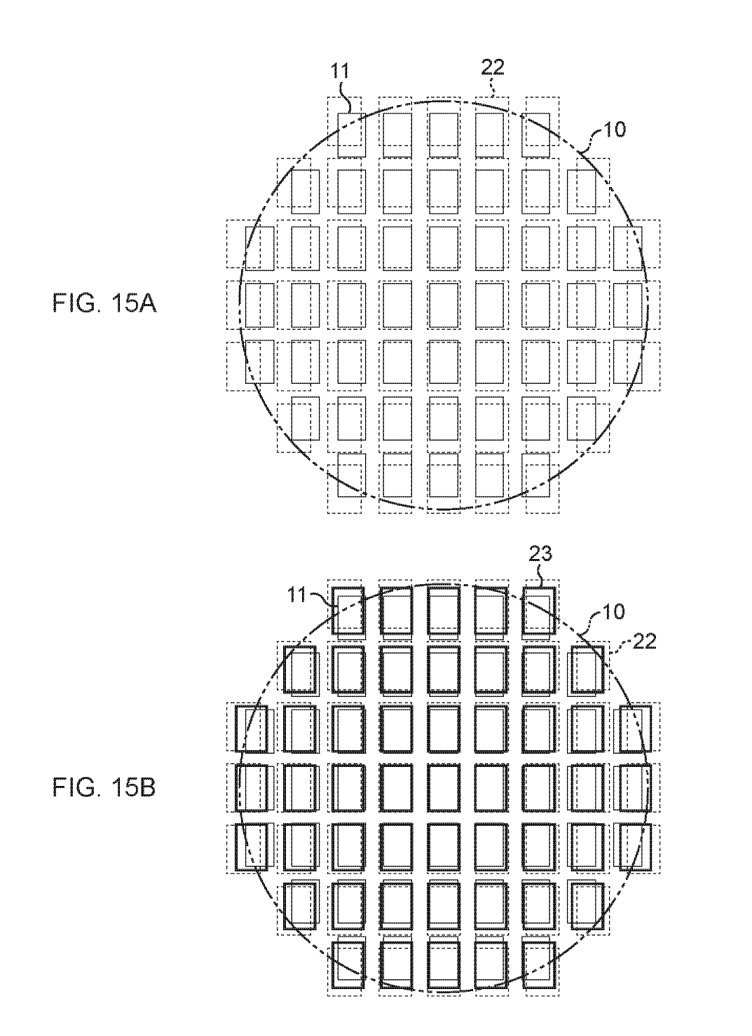

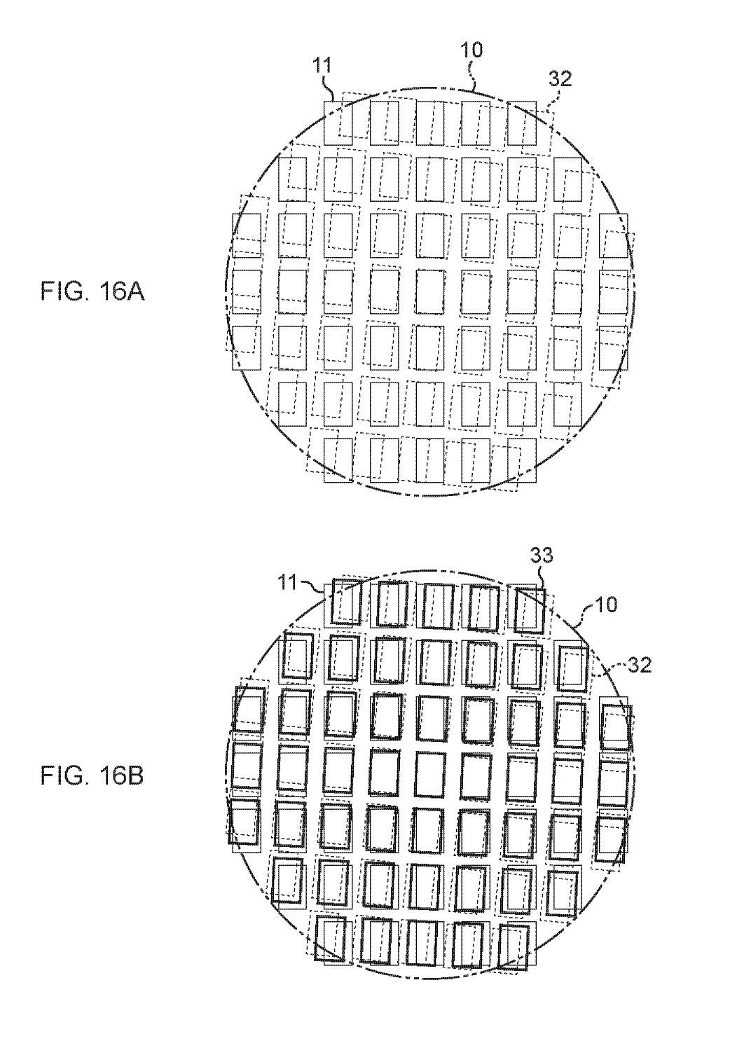

Generally, examples of the positional deviation of pattern include magnification deviation and rotational deviation other than movement in an direction (shift deviation) as described above. In the case where the shift deviation occurs, for example, a second pattern 12 is formed shifted in a direction in plan view with respect to a first portion 11 as illustrated in FIG. 11A. In the case where the magnification deviation occurs, for example, a second pattern 22 is formed enlarged or contracted in plan view with respect to the first portion 11 as illustrated in FIG. 12A. In the case where the rotational deviation occurs, for example, a second pattern 32 is formed rotated in one direction in plan view with respect to the first portion 11 as illustrated in FIG. 13A. The present invention is applicable to any of the positional deviations. For example, when the shift deviation occurs, a third pattern 13 can be formed between the first portion 11 and the second pattern 12 as illustrated in FIG. 11B. When the magnification deviation occurs, a third pattern 23 can be formed between the first portion 11 and the second pattern 22 as illustrated in FIG. 12B. When the rotational deviation occurs, a third pattern 33 can be formed between the first portion 11 and the second pattern 32 as illustrated in FIG. 13B. Further, even when two or more kinds of the shift deviation, the magnification deviation and the rotational deviation occur, appropriate alignment can be performed by superposing their respective alignments. Though the examples illustrated in FIG. 11A to FIG. 13A and FIG. 11B to FIG. 13B relate to a positional deviation in one shot, even when the shift deviation, the magnification deviation, or the rotational deviation occurs in one wafer 10 as illustrated in FIG. 14A, FIG. 15A, or FIG. 16A, the third patterns 13, 23, or 33 can be formed at appropriate positions as illustrated in FIG. 14B, FIG. 15B, or FIG. 16B.

According to the above method of manufacturing a semiconductor device or the like, when a third mask is formed, a third pattern is formed with alignment in consideration of a first positional deviation between a first portion and a second pattern, so that it is possible to improve the accuracy of alignment between materials.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A method of manufacturing a semiconductor device, comprising:
forming a first mask with a first pattern above a substrate;
forming a first portion in or above the substrate using the first mask;
forming a second mask with a second pattern above the substrate;
measuring a first positional deviation between the first portion and the second pattern;
forming a second portion in or above the substrate using the second mask;
forming a third mask with a third pattern above the substrate, the forming the third mask comprising forming the third pattern in a material film for the third mask with alignment in consideration of the first positional deviation; and
forming a third portion in or above the substrate using the third mask.

2. The method according to claim 1, wherein the forming the second mask comprises forming the second pattern in a material film for the second mask with alignment with respect to the first portion.

3. The method according to claim 1, further comprising:
measuring a second positional deviation between the first portion and the third pattern;
removing the third mask before forming the third portion, and forming a fourth mask with a fourth pattern above the substrate with alignment in consideration of the first positional deviation and the second positional deviation, when a result of the measurement of the second positional deviation does not satisfy a standard value; and
forming a fourth portion in or above the substrate using the fourth mask.

4. The method according to claim 1, wherein the forming the second portion is forming an ion implanted region.

5. A method of forming a mask, comprising:
forming a material film for mask above a substrate with a first portion and a second portion therein or thereabove; and
forming a pattern in the material film,
wherein the forming the pattern comprises performing alignment in consideration of a deviation between the first portion and a pattern in a mask used in forming the second portion.

6. The method according to claim 5, wherein the second portion is an ion implanted region.
